(19) United States
(12) Patent Application Publication
(10) Pub. No.: US 2025/0098457 A1
(43) Pub. Date: Mar. 20, 2025

(54) DISPLAY PANEL

(71) Applicant: Samsung Display Co., LTD., Yongin-si (KR)

(72) Inventors: HYUNEOK SHIN, Yongin-si (KR); JOONYONG PARK, Yongin-si (KR); SUKYOUNG YANG, Yongin-si (KR); DONGMIN LEE, Yongin-si (KR)

(21) Appl. No.: 18/790,616

(22) Filed: Jul. 31, 2024

(30) Foreign Application Priority Data
Sep. 18, 2023 (KR) 10-2023-0123854

(51) Int. Cl. H10K 59/131; H10K 59/122; H10K 59/123; H10K 59/80; H10K 59/88; H10K 102/00

(52) U.S. Cl. CPC H10K 59/131; H10K 59/122; H10K 59/123; H10K 59/80516; H10K 59/8731; H10K 59/88; H10K 2102/351

(57) ABSTRACT

A display panel includes: a base layer including a light emitting area, and a non-light emitting area being adjacent to the light emitting area, a light emitting element including a first electrode disposed in the light emitting area, a second electrode disposed on the first electrode, and a light emission pattern disposed between the first electrode and the second electrode, and a partition wall including a lower layer disposed in the non-light emitting area, and an upper layer disposed on the lower layer. The second electrode contacts a side surface of the lower layer, and the lower layer) includes layers containing different metals.

This application claims priority to Korean Patent Application No. 10-2023-0123854, filed on Sep. 18, 2023, and all the benefits accruing therefrom under 35 U.S.C. § 119, the content of which in its entirety is herein incorporated by reference.

### BACKGROUND

Embodiments of the present disclosure described herein relate to a display panel, and more particularly, relate to a display panel having an improved reliability and an enhanced visibility.

A display device is activated depending on an electric signal. The display device may include a display panel that displays an image. Among display panels, an organic light emitting display panel has a low power consumption, a high luminance, and a high reaction speed.

Among the display panels, the organic light emitting display panel includes an anode, a cathode, and a light emitting layer. The light emitting layer is separated for each of light emitting areas, and provides a common voltage for each of the light emitting areas.

### SUMMARY

An aspect of the present disclosure provides a display panel that forms a light emitting element without using a metal mask while having an increased display efficiency and an improved electrical reliability.

According to an embodiment, a display panel includes: a base layer including a light emitting area and a non-light emitting area being adjacent to the light emitting area, a light emitting element including a first electrode disposed in the light emitting area, a second electrode disposed on the first electrode, and a light emission pattern disposed between the first electrode and the second electrode, and a partition wall including a lower layer disposed in the non-light emitting area and an upper layer disposed on the lower layer, where the second electrode contacts a side surface of the lower layer, and the lower layer includes layers containing different metals.

The lower layer may include a first layer, a second layer, a third layer, a fourth layer, and a fifth layer, which are laminated sequentially, and contact resistances of the second layer and the fourth layer to the upper layer may be lower than contact resistances of the first layer, the third layer, and the fifth layer to the upper layer.

The first layer, the third layer, and the fifth layer may each include aluminum, and the second layer and the fourth layer may each include any one of molybdenum and a molybdenum alloy.

The molybdenum alloy may include molybdenum, nickel, and titanium.

A content of nickel and titanium may be not more than 50% of a total weight of the molybdenum alloy.

A thickness of the lower layer may be 5000 angstroms (Å) to 10000 Å, and a thickness of the upper layer may be 1000 Å to 2000 Å.

Thicknesses of the first layer, the third layer, and the fifth layer may each be 1000 Å to 3000 Å, and thicknesses of the second layer and the fourth layer may each be 500 Å to 1500 Å.

The upper layer may include titanium.

Side surfaces of the first to fifth layers may be aligned with each other.

Side surfaces of the second layer and the fourth layer may each protrude in a direction facing the light emitting area further than the first layer, the third layer, and the fifth layer.

The second electrode may contact the second layer and may expose the fourth layer.

The second electrode may be spaced apart from the second layer and may contact the fourth layer.

The second electrode may contact the second layer and the fourth layer.

A side surface of the upper layer may protrude in a direction facing the light emitting area further than the side surface of the lower layer.

The display panel may further include a pixel definition layer disposed on the base layer, and by which an opening exposing at least a portion of the first electrode is defined, the pixel definition layer may include an inorganic material, and the lower layer may be disposed on the pixel definition layer.

A partition wall opening overlapping the opening may be defined by the partition wall.

The display panel may further include an encapsulation layer including a lower inorganic layer covering the light emitting element and the partition wall, an upper inorganic layer disposed on the lower inorganic layer, and an organic layer disposed between the lower inorganic layer and the upper inorganic layer, and disposed in the partition wall opening.

The display panel may further include a dummy pattern disposed on the upper layer, and including the same material as at least one of the light emission pattern or the second electrode, and the dummy pattern may be covered by the lower inorganic layer.

A dummy recess exposing an upper surface of the upper layer may be defined by the dummy pattern, and the organic layer may contact the upper surface of the upper layer.

The display panel may include a transistor disposed on the base layer, a connecting electrode connecting the transistor and the first electrode, an auxiliary electrode disposed in the same layer as a layer of the connecting electrode, an inter-layer insulation layer covering the connecting electrode and the auxiliary electrode, and on which the first electrode is disposed, a pixel definition layer, by which an opening exposing at least a portion of the first electrode is defined, and an auxiliary connecting electrode disposed on the inter-layer insulation layer, and connected to the auxiliary electrode through a contact hole defined in the inter-layer insulation layer, and the lower layer may be disposed on the auxiliary connecting electrode.

### BRIEF DESCRIPTION OF THE FIGURES

The above and other objects and features of the present disclosure will become apparent by describing in detail embodiments thereof with reference to the accompanying drawings.

FIG. 1A is a perspective view of a display device according to an embodiment of the present disclosure.

FIG. 1B is an exploded perspective view of a display device according to an embodiment of the present disclosure.

FIG. 2 is a cross-sectional view of a display panel according to an embodiment of the present disclosure.

FIG. 3A is a plan view of a display panel according to an embodiment of the present disclosure.

FIG. 3B is an equivalent circuit diagram of a pixel according to an

embodiment of the present disclosure.

FIG. 4 is an enlarged plan view of a portion of a display area of a display panel according to an embodiment of the present disclosure.

FIG. 5 is a cross-sectional view taken along I-I′ of FIG. 4.

FIG. 6 is a cross-sectional view illustrating a portion of a partition wall according to an embodiment of the present disclosure.

FIG. 7 is a cross-sectional view of a display panel according to an embodiment of the present disclosure.

FIG. 8A is a cross-sectional view illustrating a portion of a partition wall according to another embodiment of the present disclosure.

FIG. 8B is a cross-sectional view illustrating a portion of a partition wall according to still another embodiment of the present disclosure.

FIG. 8C is a cross-sectional view illustrating a portion of a partition wall according to yet another embodiment of the present disclosure.

FIGS. 9A to 9E are cross-sectional views illustrating a method for manufacturing a display panel according to an embodiment of the present disclosure.

### DETAILED DESCRIPTION

In the specification, when it is mentioned that a component (or an area, a layer, a part, or the like) is “disposed on”, “connected to”, or “coupled to” another component, it means that the former component may be directly disposed on, connected to, or coupled to the latter component or a third component may be disposed between the components.

The same reference numerals denote the same components. Furthermore, in the drawings, thicknesses, ratios, dimensions of the components are exaggerated for an effective description of the technical contents. The term “and/or” includes one or more combinations that may be defined by the associated components.

In describing the various components, the terms, such as “first” and “second” may be used, but the present disclosure is not limited by the terms. The terms are simply for distinguishing the components. For example, a first component may be named a second component, and similarly the second component also may be named the first component while not departing from the scope of the present disclosure. A singular expression includes a plural expression unless an exemption is explicitly described in the context.

Furthermore, the terms, such as “under”, “below”, “on”, and “above”, are used to describe an associative relationship between the components illustrated in the drawings. The terms are relative concepts, and are described with respect to directions indicated in the drawings.

When the terms, such as “comprise” and/or “comprising”, is used in the specification, it should be understood that they specify presence of the above-mentioned features, numbers, steps, operations, components, parts, and/or combinations thereof, and do not exclude presence or addition of one or more other numbers, steps, operations, components, parts, and/or combinations thereof.

Unless otherwise defined, all terms (including technical and scientific terms) used herein have the same meaning as commonly understood by those skilled in the art to which the present disclosure pertains. It will be further understood that terms, such as those defined in commonly used dictionaries, should be interpreted as having a meaning that is consistent with their meaning in the context of the specification and relevant art and should not be interpreted in an idealized or overly formal sense unless expressly so defined herein.

Hereinafter, embodiments of the present disclosure will be described with reference to the drawings.

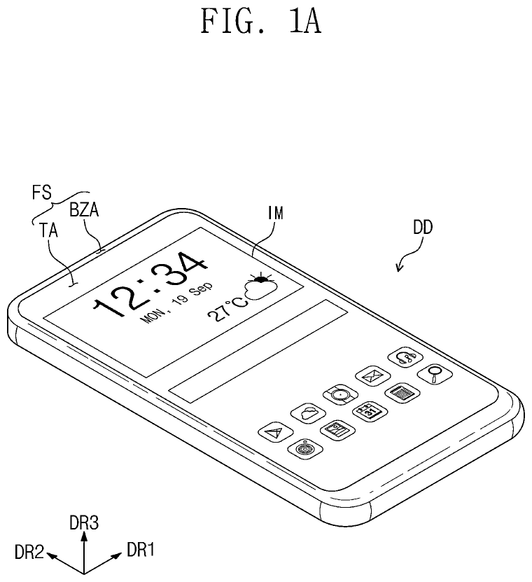

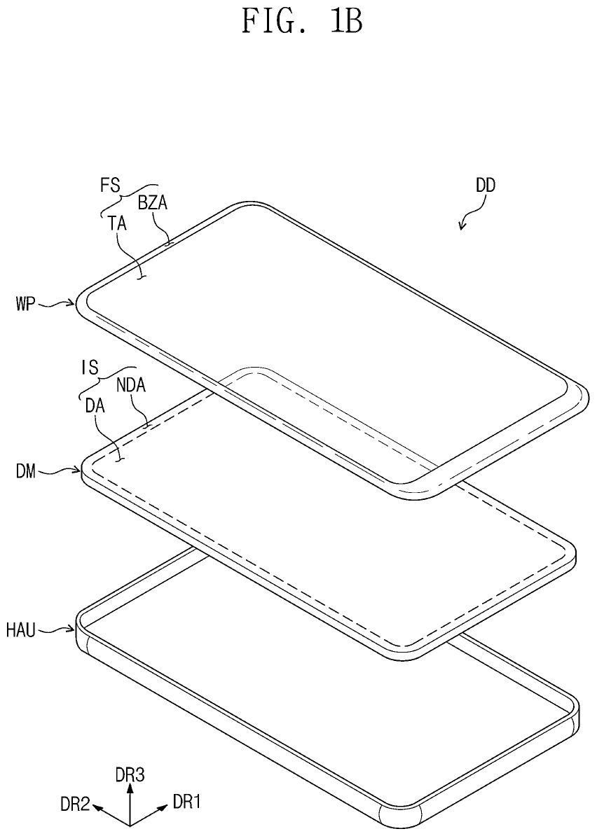

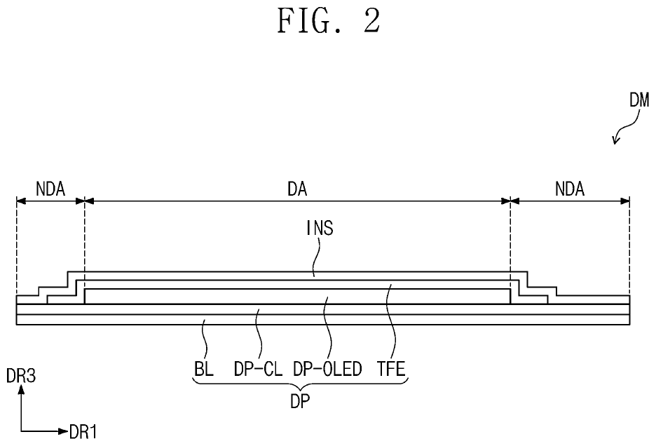

FIG. 1A is a perspective view of a display device according to an embodiment of the present disclosure. FIG. 1B is an exploded perspective view of the display device according to an embodiment of the present disclosure. FIG. 2 is a cross-sectional view of the display panel according to an embodiment of the present disclosure.

In an embodiment, a display device DD may be a component that is included in large-scale electronic devices, such as televisions, monitors, or outdoor advertising panels. Furthermore, the display device DD may be a component included in middle/small scale electronic devices, such as personal computers, notebook computers, personal digital terminals, vehicle navigation units, gaming consoles, smartphones, tablets, and cameras. They are simply suggested as embodiments, and also may be employed as other display devices as long as they do not deviate from the concept of the present disclosure. In the embodiment, it is exemplarily illustrated that the display device DD is a smartphone.

Referring to FIGS. 1A, 1B, and 2, the display device DD may display an image IM toward a third direction DR3, on a display surface FS that is parallel to a first direction DR1 and a second direction DR2. The image IM may include a still image as well as a dynamic image. FIG. 1A illustrates a watch window and icons as an example of the image IM. The display surface FS, on which the image IM is displayed, may correspond to a front surface of the display device DD.

In the embodiment, front surfaces (or upper surfaces) and rear surfaces (or lower surfaces) of members are defined with reference to a direction, in which the image IM is displayed. The front surfaces and the rear surfaces may face each other in the third direction DR3, and normal directions of the front surfaces and the rear surfaces may be parallel to the third direction DR3. Meanwhile, directions indicated by the first to third directions DR1, DR2, and DR3 are relative concepts, and may be converted to other directions. In the specification, the expression “on a plane” may mean when viewed in the third direction DR3.

As illustrated in FIG. 1B, the display device DD according to the embodiment may include a window WP, a display module DM, and a housing HAU. The window WP and the housing HAU may be coupled to each other to constitute an external appearance of the display device DD.

The window WP may include an optically transparent insulating material. In an embodiment, for example, the window WP may include glass or plastic. A front surface of the window WP may define the display surface FS of the display device DD. The display surface FS may include a transmissive area TA and a bezel area BZA. The transmissive area TA may be an optically transparent area. In an embodiment, for example, the transmissive area TA may have a visual ray transmission ratio of about 90% or more.

The bezel area BZA may be an area, of which a light transmission ratio is lower than a light transmission ratio of the transmissive area TA. The bezel area BZA may define a shape of the transmissive area TA. The bezel area BZA may be adjacent to the transmissive area TA, and may surround the transmissive area TA. Meanwhile, this is exemplarily illustrated, and in the window WP according to an embodiment of the present disclosure, the bezel area BZA may be omitted. The window WP according to an embodiment may include at least one functional layer of a fingerprint preventing layer, a hard coating layer, a reflection preventing layer, and is not limited to any one embodiment.

The display module DM may be disposed under the window WP. The display module DM may be a configuration that substantially generates the image IM. The image IM generated by the display module DM is displayed on a display surface IS of the display module DM, and is viewed to the user from an outside through the transmissive area TA.

The display module DM includes a display area DA and a non-display area NDA. The display area DA may be an area that is activated depending on an electrical signal. The non-display area NDA is adjacent to the display area DA. The non-display area NDA may surround the display area DA. The non-display area NDA is an area that is covered by the bezel area BZA, and may not be viewed from an outside.

As illustrated in FIG. 2, the display module DM according to the embodiment may include a display panel DP and an input sensor INS. Although not illustrated separately, the display device DD according to an embodiment of the present disclosure may further include a protection member disposed on a lower surface of the display panel DP or a reflection preventing member and/or a window member that is disposed on an upper surface of the input sensor INS.

The display panel DP may be a light emitting display panel, and is not particularly limited thereto. In an embodiment, for example, the display panel DP may be an organic light emitting display panel or an inorganic light emitting display panel. A light emitting layer in the organic light emitting display panel includes an organic light emitting material. The light emitting layer in the inorganic light emitting display panel includes quantum dots, quantum rods, or micro LEDs. Hereinafter, the display panel DP will be described as an organic light emitting display panel.

The display panel DP may include a base layer BL, a circuit element layer DP-CL that is disposed on the base layer BL, a display element layer DP-OLED, and an encapsulation layer TFE. The input sensor INS may be directly disposed on the encapsulation layer TFE. In the specification, the expression that “configuration “A” is directly disposed on configuration “B” means that an adhesive layer is not disposed between configuration “A” and configuration “B”.

The base layer BL may include at least one plastic film. The base layer BL is a flexible board, and may include a plastic board, a glass board, a metal board, or an organic/inorganic complex material board. In the specification, it may be considered that the display area DA and the non-display area NDA are defined in the base layer BL, and then, it also may be considered that the configurations disposed on the base layer BL are disposed to overlap the display area DA or the non-display area NDA.

The circuit element layer DP-CL includes at least one insulating layer and a circuit element. The insulating layer includes at least one inorganic layer and at least one organic layer. The circuit element includes signal lines and a driving circuit for pixels.

The circuit element layer DP-CL may be formed through a common process of manufacturing a circuit element by forming an insulating layer, a semiconductor layer, a conductive layer through a scheme, such as coating or deposition, selectively patterning the insulating layer, the semiconductor layer, and the conductive layer through photography and etching processes, and forming a semiconductor pattern, a conductive pattern, and signal lines.

The display element layer DP-OLED includes a conductive partition wall and a light emitting element. The light emitting element may include an anode (a first electrode), a light emission pattern, and a cathode (a second electrode), and the light emission pattern may at least include a functional layer.

The encapsulation layer TFE includes a plurality of thin films. Some thin films may be disposed on corresponding pixels while having a specific thickness to enhance an optical efficiency. Furthermore, some thin films are disposed to protect the light emitting elements.

The input sensor INS acquires coordinate information of an external input. The input sensor INS may have a multi-layer structure. The input sensor INS may include a single-layer or multi-layer conductive layer. The input sensor INS may include a single-layer or multi-layer insulating layer. The input sensor INS, for example, may sense an external input through a capacitive scheme.

In the present disclosure, a scheme of operating the input sensor INS is not particularly limited, and in an embodiment of the present disclosure, the input sensor INS may sense an external input in an electromagnetic induction scheme or a pressure sensitive scheme. Meanwhile, in another embodiment of the present disclosure, the input sensor INS may be omitted.

As illustrated in FIG. 1B, the housing HAU may be coupled to the window WP. The housing HAU may be coupled to the window WP to provide a specific interior space. The display module DM may be accommodated in the interior space.

The housing HAU may include a material of a relatively high stiffness. In an embodiment, for example, the housing HAU may include a plurality of frame and/or plates that include glass, plastic, or metal, or a combination thereof. The housing HAU may stably protect the configurations of the display device DD accommodated in the interior space from an external impact.

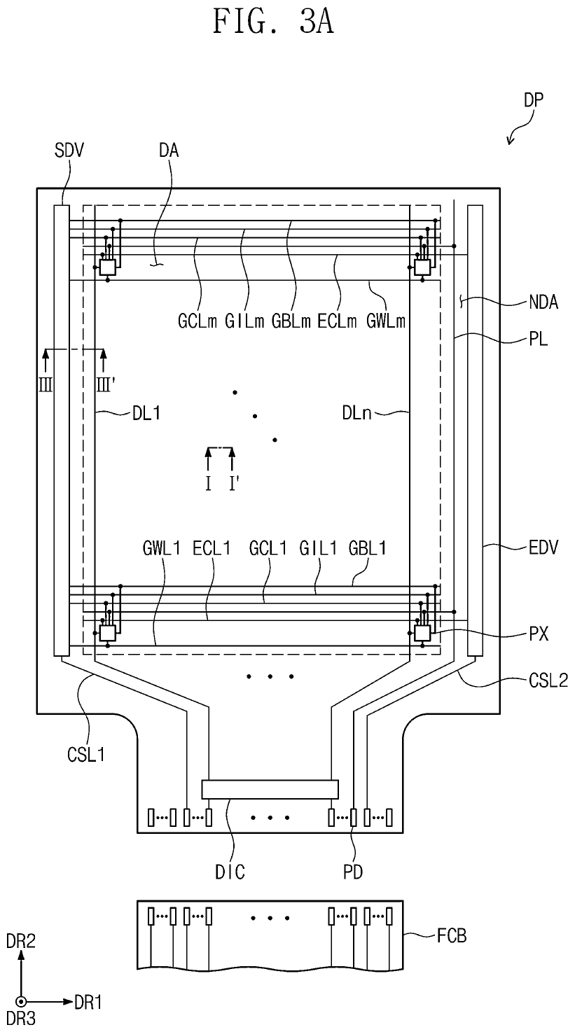

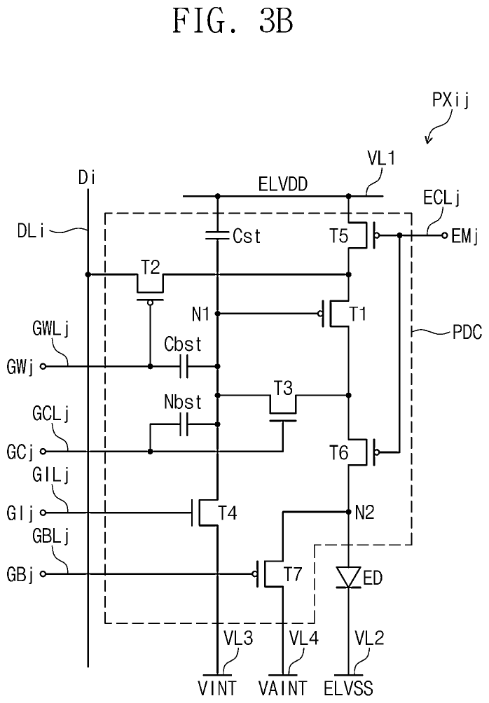

FIG. 3A is a plan view of a display panel according to an embodiment of the present disclosure. FIG. 3B is an equivalent circuit diagram of a pixel according to an embodiment of the present disclosure. As used herein, the “plan view” is a view in a thickness direction (i.e., third direction DR3) of the base layer BL.

Referring to FIG. 3A, the display area DA and the non-display area NDA around the display area DA may be defined in the display panel DP. The display area DA and the non-display area NDA may be classified depending on whether pixels PX are disposed. The pixels PX may be disposed in the display area DA. A scan driving part SDV, a data driving part, and a light emission driving part EDV may be disposed in the non-display area NDA. The data driving part may be a partial circuit that is disposed in a driver IC DIC.

The display panel DP may include the pixels PX, initializing scan lines GIL1 to GILm, compensating scan lines GCL1 to GCLm, writing scan lines GWL1 to GWLm, black scan lines GBL1 to GBLm, light emission control lines ECL1 to ECLm, data lines DL1 to DLn, first and second control lines CSL1 and CSL2, a driving voltage line PL, and a plurality of pads PD. Here, “m” and “n” are natural number of 2 or more.

The pixels PX may be connected to the initializing scan lines GIL1 to GILm, the compensating scan lines GCL1 to GCLm, the writing scan lines GWL1 to GWLm, the black scan lines GBL1 to GBLm, the light emission control lines ECL1 to ECLm, and the data lines DL1 to DLn.

The initializing scan lines GIL1 to GILm, the compensating scan lines

GCL1 to GCLm, the writing scan lines GWL1 to GWLm, and the black scan lines GBL1 to GBLm may extend in the first direction DR1 and may be electrically connected to the scan driving part SDV. The data lines DL1 to DLn may extend in the second direction DR2, and may be electrically connected to the driver IC DIC. The light emission control lines ECL1 to ECLm may extend in the first direction DR1 and may be electrically connected to the light emission driving part EDV.

The driving voltage line PL may include a part that extends in the first direction DR1 and a part that extends in the second direction DR2. The part that extends in the first direction DR1 and the part that extends in the second direction DR2 may be disposed on different layers. The driving voltage line PL may provide a driving voltage to the pixels PX.

The first control line CSL1 may be connected to the scan driving part SDV. The second control line CSL2 may be connected to the light emission driving part EDV.

The driver IC DIC, the driving voltage line PL, the first control line CSL1, and the second control line CSL2 may be electrically connected to the pads PD. A flexible circuit film FCB may be electrically connected to the pads PD through an anisotropic conductive adhesive layer. The pads PD may be pads for connecting the flexible circuit film FCB to the display panel DP. The pads PD may be connected to the corresponding pixels PX through the driving voltage line PL, the first control line CSL1, and the second control line CSL2.

Furthermore, the pads PD may further include input pads. The input pads may be pads for connecting the flexible circuit film FCB to the input sensor INS (see FIG. 2). However, the present disclosure is not limited thereto, and the input pads may be disposed in the input sensor INS (see FIG. 2), and may be connected to the pads PD and a separate circuit board in another embodiment. Alternatively, the input sensor INS (see FIG. 2) may be omitted, and may not further include input pads.

FIG. 3B exemplarily illustrate an equivalent circuit diagram of, among the plurality of pixels PX of FIG. 3A, one pixel PXij. Because the plurality of pixels PX have the same circuit structure, a detailed description of the remaining pixels PX will be replaced by a description of a circuit structure for the pixel Pxij.

Referring to FIGS. 3A and 3B, the pixel Pxij is connected to the i-th data line Dli of the data lines DL1 to DLn, the j-th initializing scan line GILj of the initializing scan lines GIL1 to GILm, the j-th compensating scan line GCLj of the compensating scan lines GCL1 to GCLm, the j-th writing scan line GWLj of the writing scan lines GWL1 to GWLm, the j-th black scan line GBLj of the black scan lines GBL1 to GBLm, the j-th light emission control line ECLj of the light emission control lines ECL1 to ECLm, first and second driving voltage lines VL1 and VL2, and first and second initializing voltage lines VL3 and VLA. “i” is an integer of not less than 1 and not more than “n”, and “j” is an integer of not less than 1 and not more than “m”.

The pixel Pxij includes a light emitting element ED and a pixel circuit PDC. The light emitting element ED may be a light emitting diode. As an example of the present disclosure, the light emitting element ED may be an organic light emitting diode including an organic light emitting layer, and the present disclosure is not particularly limited thereto. The pixel circuit PDC may control an amount of currents that flow through the light emitting element ED in correspondence to a data signal Di. The light emitting element ED may emit light with a specific luminance in correspondence to an amount of currents provided from the pixel circuit PDC.

The pixel circuit PDC may include first to seventh transistors T1, T2, T3, T4, T5, T6, and T7, and first to third capacitors Cst, Cbst, and Nbst. According to the present disclosure, a configuration of the pixel circuit PDC is not limited to the embodiment illustrated in FIG. 3B. The pixel circuit PDC illustrated in FIG. 3B simply is one example, and the configuration of the pixel circuit PDC may be modified to be carried out.

At least one of the first to seventh transistors T1, T2, T3, T4, T5, T6, and T7 may be a transistor having a low-temperature polycrystalline silicon (“LTPS”) semiconductor layer. At least one of the first to seventh transistors T1, T2, T3, T4, T5, T6, and T7 may be a transistor having an oxide semiconductor layer. In an embodiment, for example, the third and fourth transistors T3 and T4 may be oxide semiconductor transistors, and the first, second, fifth, sixth, and seventh transistors T1, T2, T5, T6, and T7 may be LTPS transistors.

Because the first transistor T1 may directly influence the brightness of the light emitting element ED, a display device of a high resolution may be implemented when the first transistor T1 includes a semiconductor layer including polycrystalline silicon of a high reliability. Furthermore, when at least one of the third transistor T3 or the fourth transistor T4, which is connected to a gate electrode of the first transistor T1, includes an oxide semiconductor, an amount of leakage currents that may flow to the gate electrode of the first transistor T1 may be reduced and power consumptions may be decreased.

Some of the first to seventh transistors T1, T2, T3, T4, T5, T6, and T7 may be P-type transistors, and the remaining ones may be N-type transistors. In an embodiment, for example, the first, second, fifth, sixth, and seventh transistors T1, T2, T5, T6, and T7 may be P-type transistors, and the third and fourth transistors T3 and T4 may be N-type transistors.

A configuration of the pixel circuit PDC according to the present disclosure is not limited to the embodiment illustrated in FIG. 3B. The pixel circuit PDC illustrated in FIG. 3B simply is one example, and the configuration of the pixel circuit PDC may be modified to be carried out. In an embodiment, for example, all of the first to seventh transistors T1, T2, T3, T4, T5, T6, and T7 may be P-type transistors or N-type transistors. Furthermore, the first, second, fifth, and sixth transistors T1, T2, T5, and T6 may be P-type transistors, and the third, fourth, and seventh transistors T3, T4, and T7 may be N-type transistors.

The j-th initializing scan line GILj, the j-th compensating scan line GCLj, the j-th writing scan line GWLj, the j-th black scan line GBLj, and the j-th light emission control line ECLj may deliver a j-th initializing scan signal Gij, a j-th compensating scan signal GCj, a j-th writing scan signal GWj, a j-th black scan signal GBj, and a j-th light emission control signal Emj to the pixel Pxij. The i-th data line Dli delivers an i-th data signal Di to the pixel Pxij. The i-th data signal Di may have a voltage level corresponding to an image signal that is input to the display device DD (see FIG. 1A).

The first and second driving voltage lines VL1 and VL2 may deliver a first driving voltage ELVDD and a second driving voltage ELVSS to the pixel Pxij, respectively. Furthermore, the first and second initializing voltage lines VL3 and VLA may deliver a first initializing voltage VINT and a second initializing voltage VAINT to the pixel Pxij, respectively.

The first transistor T1 is connected between the first driving voltage line VL1 that receives the first driving voltage ELVDD, and the light emitting element ED. The first transistor T1 includes a first electrode that is connected to the first driving voltage line VL1 via the fifth transistor T5, a second electrode that is connected to a pixel electrode (or referred to as an anode) of the light emitting element ED via the sixth transistor T6, and a third electrode (for example, a gate electrode) that is connected to one end (for example, a first node N1) of the first capacitor Cst. The first transistor T1 may receive the i-th data signal Di delivered by the i-th data line Dli and supply a driving current to the light emitting element ED depending on a switching operation of the second transistor T2.

The second transistor T2 may be connected to the data line Dli and the first electrode of the first transistor T1. The second transistor T2 includes a first electrode that is connected to the data line Dli, a second electrode that is connected to the first electrode of the first transistor T1, and a third electrode (for example, a gate electrode) that is connected to the j-th writing scan line GWLj. The second transistor T2 may be turned on depending on the writing scan signal GWj received through the j-th writing scan line GWLj, and may deliver the i-th data signal Di delivered from the i-th data line Dli to the first electrode of the first transistor T1. One end of the second capacitor Cbst may be connected to the third electrode of the second transistor T2, and an opposite end of the second capacitor Cbst may be connected to the first node N1.

The third transistor T3 is connected between the second electrode of the first transistor T1, and the first node N1. The third transistor T3 includes a first electrode that is connected to the third electrode of the first transistor T1, a second electrode that is connected to the second electrode of the first transistor T1, a third electrode (for example, a gate electrode) that is connected to the j-th compensating scan line GCLj. The third transistor T3 may be turned on depending on the j-th compensating scan signal GCj delivered through the j-th compensating scan line GCLj and may connect the third electrode of the first transistor T1 and the second electrode of the first transistor T1 to diode-connect the first transistor T1. One end of the third capacitor Nbst may be connected to the third electrode of the third transistor T3, and an opposite end of the third capacitor Nbst may be connected to the first node N1.

The fourth transistor T4 is connected between the first initializing voltage line VL3, to which the first initializing voltage VINT is applied, and the first node N1. The fourth transistor T4 includes a first electrode that is connected to the first initializing voltage line VL3, to which the first initializing voltage VINT is delivered, a second electrode that is connected to the first node N1, and a third electrode (for example, a gate electrode) that is connected to the j-th initializing scan line GILj. The fourth transistor T4 is turned on depending on the j-th initializing scan signal Gij received through the j-th initializing scan line GILj. The turn-on fourth transistor T4 delivers the first initializing voltage VINT to the first node N1 and initializes a potential (that is, a potential of the first node N1) of the third electrode of the first transistor T1.

The fifth transistor T5 includes a first electrode that is connected to the first driving voltage line VL1, a second electrode that is connected to the first electrode of the first transistor T1, and a third electrode (for example, a gate electrode) that is connected to the j-th light emission control line ECLj. The sixth transistor T6 includes a first electrode that is connected to the second electrode of the first transistor T1, a second electrode that is connected to a pixel electrode of the light emitting element ED, and a third electrode (for example, a gate electrode) that is connected to the j-th light emission control line ECLj.

The fifth and sixth transistors T5 and T6 are turned on at the same time depending on a j-th light emission control signal Emj that is received through the j-th light emission control line ECLj. The first driving voltage ELVDD applied through the turned-on fifth transistor T5 may be delivered to the light emitting element ED through the sixth transistor T6 after being compensated for through the diode -connected first transistor T1.

The seventh transistor T7 includes a first electrode connected to the second initializing voltage line VL4, to which the second initializing voltage VAINT is delivered, a second electrode that is connected to the second electrode of the sixth transistor T6, and a third electrode (for example, a gate electrode) that is connected to the black scan line GBLj. The second initializing voltage VAINT may have a voltage level that is lower than a voltage level of the first initializing voltage VINT.

One end of the first capacitor Cst may be connected to the third electrode of the first transistor T1, and an opposite end of the first capacitor Cst may be connected to the first driving voltage line VL1. A cathode of the light emitting element ED may be connected to the second driving voltage line VL2 that delivers the second driving voltage ELVSS. The second driving voltage ELVSS may have a voltage level that is lower than a voltage level of the first driving voltage ELVDD.

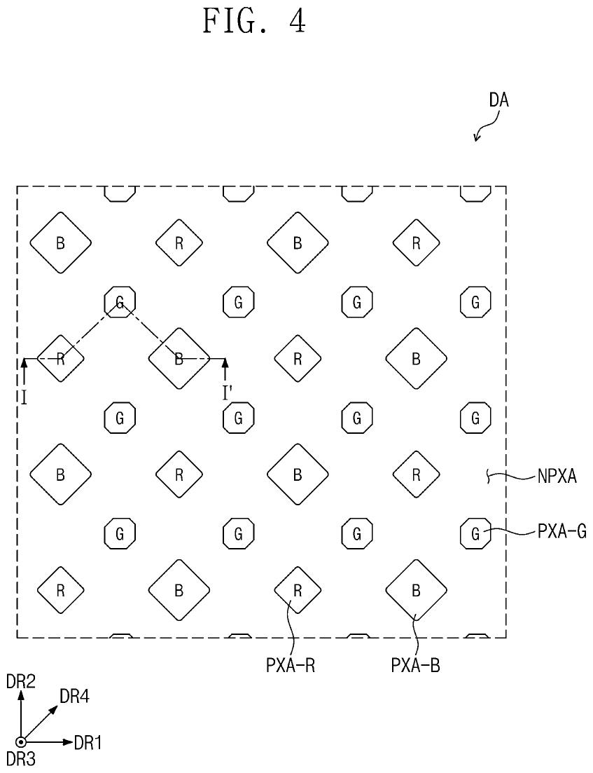

FIG. 4 is an enlarged plan view of a portion of the display area of the display panel according to an embodiment of the present disclosure. FIG. 4 illustrates a plane of the display module DM viewed from a top of the display surface IS (see FIG. 1B) of the display module DM (see FIG. 2), and illustrates an arrangement of light emitting areas PXA-R, PXA-G, and PAX-B.

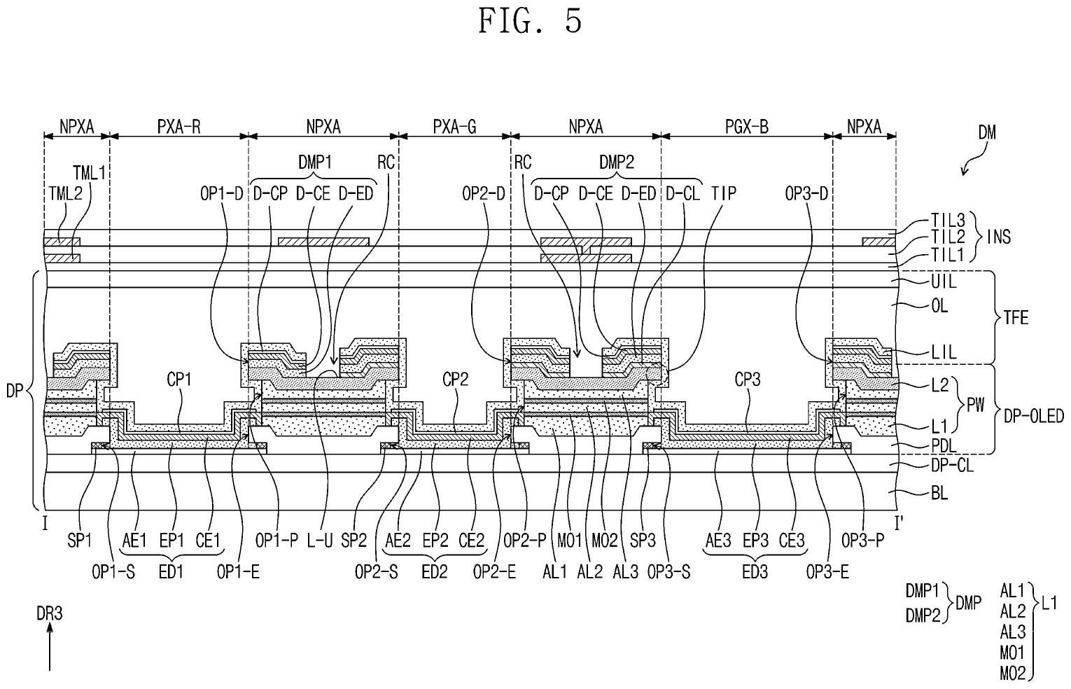

The first to third light emitting areas PXA-R, PXA-G, and PXA-B may correspond to first to third light emitting openings OP1-E, OP2-E, and OP3-E defined in a pixel definition layer PDL, which will be described in FIG. 5, in a one-to-one relationship.

Referring to FIG. 4, the display area DA may include the first to third light emitting areas PXA-R, PXA-G, and PXA-B, and a non-light emitting area NPXA that surrounds the first to third light emitting areas PXA-R, PXA-G, and PXA-B. The first to third light emitting areas PXA-R, PXA-G, and PXA-B may correspond to the areas, in which the lights provided from light emitting elements ED1, ED2, and ED3 (see FIG. 5) are emitted. The first to third light emitting areas PXA-R, PXA-G, and PXA-B may be classified depending on the colors of the lights emitted toward an outside of the display module DM (see FIG. 2).

The first to third light emitting areas PXA-R, PXA-G, and PXA-B may provide first to third color lights having different colors. In an embodiment, for example, the first color light may have a red color, the second color light may have a green color, and the third color light may have a blue color. However, the example of the first to third color lights is not limited to the example.

The non-light emitting area NPXA may set borders of the first to third light emitting areas PXA-R, PXA-G, and PXA-B, and because a structure including a light shielding material is disposed at a part that overlaps the non-light emitting area NPXA, color mixing of the first to third light emitting areas PXA-R, PXA-G, and PXA-B may be prevented.

The number of each of the first to third light emitting areas PXA-R, PXA-G, and PXA-B may be plural, and the first to third light emitting areas PXA-R, PXA-G, and PXA-B may be repeatedly disposed while having a specific arrangement form. In an embodiment, for example, the first and third light emitting areas PXA-R and PXA-B may be alternately arranged along the first direction DR1 to constitute a ‘first group’. The second light emitting areas PXA-G may be arranged along the first direction DR1 to constitute a ‘second group’. The number of each of the ‘first groups’ and the ‘second groups’ may be plural, and the first groups and the second groups may be alternately arranged along the second direction DR2. One second light emitting area PXA-G may be disposed to be spaced apart from one first light emitting area PXA-R or one third light emitting area PXA-B in a fourth direction DR4. The fourth direction DR4 may be defined as a direction between the first and second directions DR1 and DR2.

Meanwhile, FIG. 4 exemplarily illustrates an arrangement form of the first to third light emitting areas PXA-R, PXA-G, and PXA-B, and the present disclosure is not limited thereto and the first to third light emitting areas PXA-R, PXA-G, and PXA-B may be arranged in various forms. In an embodiment, the first to third light emitting areas PXA-R, PXA-G, and PXA-B, as illustrated in FIG. 4, may have a pentile™ arrangement form. Alternatively, the first to third light emitting areas PXA-R, PXA-G, and PXA-B may have a stripe arrangement form or a diamond pixel™ arrangement form.

The first to third light emitting areas PXA-R, PXA-G, and PXA-B may have various shapes on a plane. In an embodiment, for example, the first to third light emitting areas PXA-R, PXA-G, and PXA-B may have a shape, such as a polygonal shape, a circular shape, or an elliptical shape. FIG. 4 exemplarily illustrates the first and third light emitting areas PXA-R and PXA-B having a rectangular shape (or rhombus shape) in a plan view, and the second light emitting area PXA-G having an octagonal shape.

The first to third light emitting areas PXA-R, PXA-G, and PXA-B may have the same shape in a plan view, or at least some of them may have different shapes. FIG. 4 exemplarily illustrates the first and third light emitting areas PXA-R and PXA-B having the same shape in a plan view, and the second light emitting area PXA-G having a shape that is different from shapes of the first and third light emitting areas PXA-R and PXA-B.

At least some of the first to third light emitting areas PXA-R, PXA-G, and PXA-B may have different areas in a plan view. In an embodiment, the area of the first light emitting area PXA-R that emits the red light may be larger than the area of the second light emitting area PXA-G that emits the green light, and may be smaller than the area of the third light emitting area PXA-B that emits the blue light.

However, a size relationship between the first to third light emitting areas PXA-R, PXA-G, and PXA-B depending on the light emission color is not limited thereto, and may vary depending on a design of the display module DM (see FIG. 2). Furthermore, the present disclosure is not limited thereto, and the first to third light emitting areas PXA-R, PXA-G, and PXA-B may have the same area in a plan view.

As the first to third light emitting areas PXA-R, PXA-G, and PXA-B form lights of different wavelength bands, the first to third light emitting areas PXA-R, PXA-G, and PXA-B require individual inorganic layers that may optimize a light emission efficiency to agree with the respective wavelengths to enhance the efficiency of the light emitting elements.

Meanwhile, the shape, the area, the arrangement, and the like of the first to third light emitting areas PXA-R, PXA-G, and PXA-B of the display module DM (see FIG. 2) of the present disclosure may be variously designed depending on the colors of the emitted lights or the size and the configuration of the display module DM (see FIG. 2), and are not limited to the embodiment illustrated in FIG. 4.

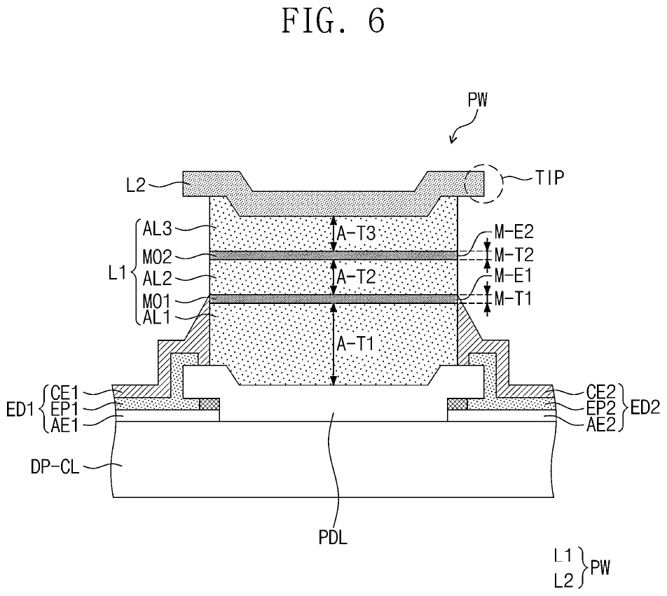

FIG. 5 is a cross-sectional view taken along I-I′ of FIG. 4. FIG. 6 is a cross-sectional view illustrating a portion of a partition wall according to an embodiment of the present disclosure.

Referring to FIG. 5, the display module DM according to an embodiment may include the display panel DP, and the input sensor INS that is disposed directly on the display panel DP. The input sensor INS may correspond to the input sensor INS described in FIG. 2.

The display panel DP according to the embodiment may include the base layer BL, the circuit element layer DP-CL, the display element layer DP-OLED, and the encapsulation layer TFE. The display element layer DP-OLED may include the light emitting elements ED1, ED2, and ED3, sacrificial patterns SP1, SP2, and SP3, the pixel definition layer PDL, a partition wall PW, and a dummy pattern DMP.

The base layer BL may provide a base surface, on which the circuit element layer DP-CL, the display element layer DP-OLED, and the encapsulation layer TFE may be disposed. The base layer BL may be flexible or rigid. In an embodiment, for example, the base layer BL may include a synthetic resin film or any one of glass or metal. FIG. 5 illustrates a single-layer base layer BL, but the present disclosure is not limited thereto, and the base layer BL may be provided as a multi-layer, in which a plurality of organic layers and a plurality of inorganic layers are alternately disposed in another embodiment.

The circuit element layer DP-CL may be disposed on the base layer BL. The circuit element layer DP-CL may include a plurality of insulating layers, and conductive patterns that are disposed between the plurality of insulating layers.

The circuit element layer DP-CL may include at least one transistor that is connected to each of the light emitting elements ED1, ED2, and ED3 included in the display element layer DP-OLED and the insulating layers. A structure of the at least one transistor is not limited to any one as long as it is for driving the pixels PX (see FIG. 3A). The insulating layers may be provided with a single layer including any one of an inorganic layer and an organic layer or may be provided with a multi-layer, in which different inorganic layers are laminated, but the present disclosure is not limited thereto.

The display element layer DP-OLED may be disposed on the circuit element layer DP-CL. In the circuit element layer DP-CL, the light emitting elements ED1, ED2, and ED3 may include the first light emitting element ED1, the second light emitting element ED2, and the third light emitting element ED3.

The first light emitting element ED1 may include a first anode AE1, a first light emission pattern EP1, and a first cathode CE1, and the second light emitting element ED2 may include a second anode AE2, a second light emission pattern EP2, and a second cathode CE2, and the third light emitting element ED3 may include a third anode AE3, a third light emission pattern EP3, and a third cathode CE3. In an embodiment, the first light emission pattern EP1 may provide a light of a red color, the second light emission pattern EP2 may provide a light of a green color, and the third light emission pattern EP3 may provide a light of a blue color.

The first to third anodes AE1, AE2, and AE3 may be individually patterned and may be spaced apart from each other. The first to third anodes AE1, AE2, and AE3 may be conductive. In an embodiment, for example, the first to third anodes AE1, AE2, and AE3 may be formed of various materials as long as the materials are of a conductive material, such as a metal, a transparent conductive oxide (“TCO”), or a conductive polymer material.

Although it is illustrated that each of the first to third anodes AE1, AE2, and AE3 has a single layer, but this is exemplary, and each of the first to third anodes AE1, AE2, and AE3 may have a multi-layer structure, and one of the first to third anodes AE1, AE2, and AE3 may have a single-layer structure and another one may have a multi-layer structure, and the present disclosure is not limited to any one embodiment.

The first to third light emission patterns EP1, EP2, and EP3 may be disposed on the corresponding first to third anodes AE1, AE2, and AE3, respectively. The first to third light emission patterns EP1, EP2, and EP3 may be patterned by a tip part TIP that is defined in the partition wall PW. A hole control layer may be further disposed between each of the first to third light emission patterns EP1, EP2, and EP3 and the corresponding first to third anodes AE1, AE2, and AE3. Furthermore, each of the first to third light emission patterns EP1, EP2, and EP3 may further include an electron control layer that is disposed between the corresponding first to third cathodes CE1, CE2, and CE3. Each of the first to third light emission patterns EP1, EP2, and EP3 may further include an electron control layer that is disposed between the corresponding first to third anodes AE1, AE2, and AE3.

The first to third cathodes CE1, CE2, and CE3 may provide a plurality of patterns that are spaced apart from each other. The first to third cathodes CE1, CE2, and CE3 may be conductive. In an embodiment, for example, the first to third cathodes CE1, CE2, and CE3 may be formed of various materials as long as the materials are of a conductive material, such as a metal, a transparent conductive oxide TCO, or a conductive polymer material. The first to third cathodes CE1, CE2, and CE3 may be patterned by a tip part TIP that is defined by the partition wall PW.

The pixel definition layer PDL may be disposed on the circuit element layer DP-CL. In the embodiment, the pixel definition layer PDL may be an insulating film including an inorganic material. In an embodiment, for example, the pixel definition layer PDL may include a silicon oxide, a silicon nitride, or a combination thereof. According to an embodiment, the pixel definition layer PDL may have a two-layer structure, in which a silicon oxide layer and a silicon nitride layer are sequentially laminated. However, this is an illustrative description, and when the pixel definition layer PDL may be an insulating film including an inorganic material, the material and whether it is a single layer or multi-layer may be variously changed, and the present disclosure is not limited to any one embodiment.

In the embodiment, the pixel definition layer PDL may define the first to third light emitting openings OP1-E, OP2-E, and OP3-E therein. The first light emission opening OP1-E may expose at least a portion of the first anode AE1. The first light emitting area PXA-R may be defined as an area of an upper surface of the first anode AE1, which is exposed by the first light emitting opening OP1-E. The second light emitting opening OP2-E may expose at least a portion of the second anode AE2. The second light emitting area PXA-G may be defined as an area of an upper surface of the second anode AE2, which is exposed by the second light emitting opening OP2-E. The third light emitting opening OP3-E may expose at least a portion of the third anode AE3. The third light emitting area PXA-B may be defined as an area of an upper surface of the third anode AE3, which is exposed by the third light emitting opening OP3-E.

The display panel DP according to an embodiment may further include the sacrificial patterns SP1, SP2, and SP3. The sacrificial patterns SP1, SP2, and SP3 may include the first sacrificial pattern SP1, the second sacrificial pattern SP2, and the third sacrificial pattern SP3. The first to third sacrificial patterns SP1, SP2, and SP3 may be disposed on edges of the corresponding first to third anodes AE1, AE2, and

AE3, respectively. The first to third sacrificial patterns SP1, SP2, and SP3 may be covered by the corresponding light emission patterns EP1, EP2, and EP3 and the pixel definition layer PDL. The sacrificial patterns SP1, SP2, and SP3 may include an amorphous transparent conductive oxide.

The sacrificial patterns SP1, SP2, and SP3 may be formed through a wet etching process. The sacrificial patterns SP1, SP2, and SP3 may have a higher etching rate than etching rates of the first to third anodes AE1, AE2, and AE3. Through this, in an etching process of forming the first to third light emitting openings OP1-E, OP2-E, and OP3-E in the pixel definition layer PDL, the sacrificial patterns SP1, SP2, and SP3 may prevent the first to third anodes AE1, AE2, and AE3 from being etched together with the pixel definition layer PDL.

In the embodiment, the sacrificial patterns SP1, SP2, and SP3 may include first to third sacrificial openings OP1-S, OP2-S, and OP3-S, respectively. The first to third sacrificial openings OP1-S, OP2-S, and OP3-S may overlap the corresponding first to third light emitting openings OP1-E, OP2-E, and OP3-E in a plan view, respectively. Each of the first to third sacrificial patterns SP1, SP2, and SP3 may exposed at least a portion of the corresponding one of the first to third anodes AE1, AE2, and AE3.

Each of the first to third sacrificial patterns SP1, SP2, and SP3 may be covered by one side surface of the pixel definition layer PDL that defines the corresponding one of the first to third light emitting openings OP1-E, OP2-E, and OP3-E, the corresponding one of the first to third anodes AE1, AE2, and AE3, and the corresponding one of the first to third light emission patterns EP1, EP2, and EP3.

Each of the first to third sacrificial patterns SP1, SP2, and SP3 may include a transparent conductive oxide. The transparent conductive oxide may include a indium tin oxide (“ITO”), an indium zinc oxide (“IZO”), a zinc oxide, an indium oxide, an Indium gallium oxide, an indium gallium zinc oxide (“IGZO”), or an aluminum zinc oxide.

In the embodiment, the partition wall PW may be disposed on the pixel definition layer PDL. The partition wall PW may overlap the non-light emitting area NPXA. The partition wall PW may include first to third partition wall openings OP1-P, OP2-P, and OP3-P.

The first to third partition wall openings OP1-P, OP2-P, and OP3-P may overlap the corresponding first to third light emitting areas PXA-R, PXA-G, and PXA-B, respectively, in a one-to-one relationship. Each of the first to third partition wall openings OP1-P, OP2-P, and OP3-P may define an opening space that is integral with the corresponding light emitting opening. Accordingly, the corresponding light emitting elements ED1, ED2, and ED3 may be disposed in the partition wall openings OP1-P, OP2-P, and OP3-P and the light emitting openings OP1-E, OP2-E, and OP3-E, which are integral. Furthermore, the partition wall openings OP1-P, OP2-P, and

OP3-P and the light emitting openings OP1-E, OP2-E, and OP3-E, which are integral, may expose portions of the corresponding anodes AE1, AE2, and AE3.

The partition wall PW according to an embodiment may include a lower layer L1, and an upper layer L2 that is disposed on the lower layer L1. The lower layer L1 may be disposed on the pixel definition layer PDL.

The lower layer L1 may include a conductive material. The lower layer L1 according to the present disclosure may be a multi-layer, in which different metal layers are laminated. In an embodiment, for example, the lower layer L1 may include first to fifth layers AL1, MO1, AL2, MO2, and AL3 that are sequentially laminated on the pixel definition layer PDL. According to the present disclosure, contact resistances of the second layer MO1 and the fourth layer MO2 to the upper layer L2 may be lower than contact resistances of the first layer AL1, the third layer AL2, and the fifth layer AL3 to the upper layer L2.

The first layer AL1, the third layer AL2, and the fifth layer AL3 may include the same first material, and the second layer MO1 and the fourth layer MO2 may include the same second material that is different from the first material. In an embodiment, for example, the first layer AL1, the third layer AL2, and the fifth layer AL3 may each include aluminum Al, and the second layer MO1 and the fourth layer MO2 may each include any one of molybdenum (Mo) and a molybdenum alloy.

In the present disclosure, the molybdenum alloy may be molybdenum (Mo)-nickel (Ni)-titanium (Ti). According to an embodiment, a content of nickel (Ni)-titanium (Ti) in a total weight of the molybdenum (Mo)-nickel (Ni)-titanium (Ti) alloy may be 50% or less. When the content of nickel (Ni)-titanium (Ti) in the total weight of the molybdenum (Mo)-nickel (Ni)-titanium (Ti) alloy is more than 50%, a contact resistance to the upper layer L2 may be increased.

Referring to FIG. 6, a total thickness of the lower layer L1 may be not less than 5000 Å and not more than 10000 Å. The total thickness of the upper layer L2 may be not more than 1000 Å and not more than 2000 Å.

Thicknesses of the first layer AL1, the third layer AL2, and the fifth layer AL3 in the lower layer L1 may each be not less than 1000 Å and not more than 3000 Å. Thicknesses of the second layer MO1 and the fourth layer MO2 in the lower layer L1 may each be not less than 500 Å and not more than 1500 Å.

According to an embodiment, the thicknesses of the first layer AL1, the third layer AL2, and the fifth layer AL3 may be different from each other. In an embodiment, for example, a thickness A-T1 of the first layer AL1 may be 2500 Å, a thickness A-T2 of the third layer AL2 may be 1500 Å, and a thickness A-T3 of the fifth layer AL3 may be 1500 Å. A thickness M-T1 of the second layer MO1 and a thickness M-T2 of the fourth layer MO2 may each be 800 Å, and the thickness of the upper layer L2 may be 2000 Å.

In an embodiment, the upper layer L2 may include a metal or a non-metal. In an embodiment, for example, the metal may include gold (Au), silver (Ag), aluminum (Al), magnesium (Mg), lithium (Li), molybdenum (Mo), titanium (Ti), copper (Cu), or an alloy. The non-metal may include silicon, a silicon oxide, a silicon nitride, a silicon oxynitride, a metal oxide, a metal nitride, or a combination thereof, and the metal oxide may include a transparent conductive oxide (TCO).

According to the present disclosure, when the lower layer L1 includes only aluminum, the lower layer L1 may be oxidized whereby a contact resistance to the upper layer L2 may be increased.

According to an embodiment, a side surface of the upper layer L2 protrude in a direction that faces the light emitting areas PXA-R, PXA-G, and PXA-B further than a side of the lower layer L1. The side surface of the upper layer L2, which protrudes further than that side of the lower layer L1, may be defined as the tip part TIP. The tip part TIP defined by the partition wall PW may be formed in an undercut shape due to a difference between the etching rates of the lower layer L1 and the upper layer L2.

According to the present disclosure, the anodes AE1, AE2, and AE3, the light emission patterns EP1, EP2, and EP3, and cathodes CE1, CE2, and CE3 included in the light emitting elements ED1, ED2, and ED3 may be individually patterned in the corresponding partition wall openings OP1-P, OP2-P, and OP3-P through the tip part TIP defined by the partition wall PW.

The first light emission pattern EP1 and the first cathode CE1 may be disposed in the first partition wall opening OP1-P, the second light emission pattern EP2 and the second cathode CE2 may be disposed in the second partition wall opening OP2-P, and the third light emission pattern EP3 and the third cathode CE3 may be disposed in the third partition wall opening OP3-P. Each of the first to third cathodes CE1, CE2, and CE3 may contact a side surface of the lower layer L1 that defines the first to third partition wall openings OP1-P, OP2-P, and OP3-P.

As illustrated in FIG. 6, each of the first to third cathodes CE1, CE2, and CE3 may contact a side surface of the first layer AL1 and a side surface of the second layer MO1 in the partition wall PW. The first to third cathodes CE1, CE2, and CE3 may expose side surfaces of the third to fifth layers AL2, MO2, and AL3.

In the embodiment, the first to third cathodes CE1, CE2, and CE3 may be physically separated from each other by the upper layer L2 that forms the tip part TIP, and may be disposed in the corresponding first to third light emitting partition wall opening OP1-P, OP2-P, and OP3-P. Accordingly, the first to third cathodes CE1, CE2, and CE3 may be spaced apart from each other while the partition wall PW being interposed therebetween. According to the present disclosure, the first to third cathodes CE1, CE2, and CE3 may contact the lower layer L1 in the partition wall PW including the conductive material to be electrically connected to each other so as to be provided with a common voltage.

The lower layer L1 may have a thickness that is greater than a thickness of the upper layer L2. In an embodiment, the lower layer L1 has an electrical conductivity and a thickness that are greater than an electrical conductivity and a thickness of the upper layer L2, respectively, and thus, decrease contact resistances with the first to third cathodes CE1, CE2, and CE3. Accordingly, a common cathode voltage may be uniformly provided to the light emitting areas PXA-R, PXA-G, and PXA-B.

According to the present disclosure, the light emission patterns EP1, EP2, and EP3 may be sequentially patterned and deposited in units of pixels by the tip part TIP defined by the partition wall PW. That is, the light emission patterns EP1, EP2, and EP3 may be commonly formed on the entire surface of the base layer BL by using an open mask, and may be easily patterned and deposited in a unit of pixels by the partition wall PW.

Meanwhile, when the light emission patterns are patterned by using a fine metal mask (“FMM”), a separate support spacer that protrudes from the conductive partition wall has to be provided to support the fine metal mask. Furthermore, the fine metal mask is spaced apart from a base surface, on which is patterned, by heights of the partition wall and the spacer, there is a limit in implementing a high resolution. Furthermore, because the fine metal mask contacts the spacer, foreign substances may be left in the spacer after the process of patterning the light emission patterns or the spacer may be stuck by the fine metal mask and be damaged. Accordingly, a defective display panel may be formed.

According to this embodiment, because it includes the partition wall PW including a conductive material, the light emitting elements ED1, ED2, and ED3 may be easily physically separated from each other. Accordingly, a current leakage or a driving error between the adjacent light emitting areas PXA-R, PXA-G, and PXA-B may be prevented, and the light emitting elements ED1, ED2, and ED3 may be independently driven.

In particular, because the light emission patterns EP1, EP2, and EP3 are sequentially patterned without using a mask that contacts an internal configuration in the display area DA (see FIG. 2), the display panel DP having a reduced defective rate and an improved process reliability may be provided. Furthermore, as patterning is possible even though a separate support spacer that protrudes from the partition wall PW is not provided, the areas of the light emitting areas PXA-R, PXA-G, and PXA-B may be miniaturized, and thus, the display panel DP that may easily implement a high resolution may be provided.

Furthermore, when a large-area display panel DP is manufactured, process costs may be reduced by omitting the production of a large-area mask and the process may be unaffected by defects that may occur in the large-area mask, and thus the display panel DP with an improved reliability may be provided.

Referring to FIG. 5 again, the display panel DP according to the embodiment may further include capping patterns CP1, CP2, and CP3. The capping patterns CP1, CP2, and CP3 may include the first capping pattern CP1, the second capping pattern CP2, and the third capping pattern CP3.

The first to third capping patterns CP1, CP2, and CP3 are disposed on the corresponding first to third cathodes CE1, CE2, and CE3, and may be disposed in the first to third partition wall openings OP1-P, OP2-P, and OP3-P.

The first to third capping patterns CP1, CP2, and CP3 may be directly disposed on the corresponding cathodes CE1, CE2, and CE3 to protect the first to third cathodes CE1, CE2, and CE3 in the subsequent process. Each of the first to third capping patterns CP1, CP2, and CP3 may include an organic material.

The display panel DP according to the embodiment may further include the dummy pattern DMP. The dummy pattern DMP may include a first dummy pattern DMP1 and a second dummy pattern DMP2.

The first dummy pattern DMP1 may be disposed on the partition wall PW that is adjacent to the first light emitting element ED1, and the second dummy pattern DMP2 may be disposed on the partition walls PW that are adjacent to the second light emitting element ED2 and the third light emitting element ED3. According to one embodiment, a dummy recess RC may be defined by the dummy pattern DMP. The dummy recess RC may expose an upper surface of the partition wall PW that overlaps the non-light emitting area NPXA.

In an embodiment, for example, the upper surface of the partition wall PW disposed between the first light emitting element ED1 and the second light emitting element ED2 may be exposed by the dummy recess RC defined between the first dummy pattern DMP1 and the second dummy pattern DMP2, and the upper surface of the partition wall PW disposed between the second light emitting element ED2 and the third light emitting element ED3 may be exposed by the dummy recess RC defined between the adjacent second dummy patterns DMP2.

According to an embodiment, a thickness of the second dummy pattern DMP2 may be greater than a thickness of the first dummy pattern DMP1.

Each of the first dummy pattern DMP1 and the second dummy pattern DMP2 may include a first layer D-ED, a second layer D-CE, and a third layer D-CP. The second dummy pattern DMP2 may further include an additional layer D-CL that is disposed between the partition wall PW and the first layer D-ED. The first layer D-ED may include the same material as a material of the light emission pattern included in the adjacent light emitting element. The second layer D-CE may include the same material as materials of the first to third cathodes CE1, CE2, and CE3. The third layer D-CP may include the same material as materials of the first to third capping patterns CP1, CP2, and CP3. The additional layer D-CL may include an inorganic material.

The first and second dummy patterns DMP1 and DMP2 may define first to third dummy openings OP1-D, OP2-D, and OP3-D therein corresponding to the first to third light emitting openings OP1-E, OP2-E, and OP3-E. The first dummy opening OP1-D may be defined by inner surfaces of the first dummy patterns DMP1 that are adjacent to the first light emitting element ED1, the second dummy opening OP2-D may be defined by inner surfaces of the second dummy patterns DMP2 that are adjacent to the second light emitting element ED2, and the third dummy opening OP3-D may be defined by the second dummy patterns DMP2 that are adjacent to the third light emitting element ED3.

The encapsulation layer TFE according to the embodiment may include a lower inorganic layer LIL, an organic layer OL, and an upper inorganic layer UIL.

The lower inorganic layer LIL is disposed on the display element layer DP-OLED and may cover the light emitting elements ED1, ED2, and ED3. The lower inorganic layer LIL may include any one of a silicon oxynitride or a silicon nitride. The lower inorganic layer LIL may protect the light emitting elements ED1, ED2, and ED3 from moisture and/or oxygen. The lower inorganic layer LIL may be passed through at a portion, at which the portion overlaps the dummy recess RC in a plan view by etching process. Accordingly, the lower inorganic layer LIL may expose the upper surface of the partition wall PW that overlaps the dummy recess RC in a plan view.

The organic layer OL may be disposed on the lower inorganic layer LIL. The organic layer OL may protect the light emitting elements ED1, ED2, and ED3 from foreign substances, such as dust particles. The organic layer OL may include an acrylic-based organic layer, but the present disclosure is not limited thereto. The organic layer OL may contact the upper surface of the partition wall PW exposed from the dummy recess RC.

The upper inorganic layer UIL is disposed on the organic layer OL. The upper inorganic layer UIL may include any one of a silicon nitride, a silicon oxynitride, a silicon oxide, a titanium oxide, and an aluminum oxide.

The display module DM according to an embodiment may include an input sensor INS. The input sensor INS may be disposed on the display panel DP. The input sensor INS may include at least one conductive layer and at least one insulating layer. In the embodiment, the input sensor INS may include a first sensing insulating layer TIL1, a first conductive layer TML1, a second sensing insulating layer TIL2, a second conductive layer TML2, and a third sensing insulating layer TIL3.

The first sensing insulating layer TIL1 may be directly disposed on the upper inorganic layer UIL. The first conductive layer TML1 is disposed on the first sensing insulating layer TIL1. The second sensing insulating layer TIL2 covers the first conductive layer TML1 and is disposed on the first sensing insulating layer TIL1. The second conductive layer TML2 is disposed on the second sensing insulating layer TIL2. The third sensing insulating layer TIL3 covers the second conductive layer TML2 and is disposed on the third sensing insulating layer TIL3. The first conductive layer TML1 and the second conductive layer TML2 may overlap the non-light emitting area NPXA. Accordingly, the first conductive layer TML1 and the second conductive layer TML2 may overlap with the partition wall PW in a plan view.

The first to third sensing insulating layers TIL1, TIL2, and TIL3 may be an inorganic layer including at least one of a silicon nitride, a silicon oxynitride, or a silicon oxide.

Each of the first conductive layer TML1 and the second conductive layer TML2 may have a single-layer structure or a multi-layer structure that is laminated along the third direction DR3. The second conductive layer TML2 may include conductive lines that define mesh-shaped electrodes. At least one of the conductive patterns of the first conductive layer TML1 or the conductive patterns of the second conductive layer TML2 may be connected to each other through a contact hole that passes through the second sensing insulating layer TIL2.

The first conductive layer TML1 and the second conductive layer TML2 of a single-layer structure may include a metal layer or a transparent conductive layer. The metal layer may include molybdenum, silver, titanium, copper, or aluminum, or an alloy thereof. The transparent conductive layer may include a transparent conductive oxide, such as an indium tin oxide, an indium zinc oxide, a zinc oxide, or an indium zinc tin oxide. In addition, the transparent conductive layer may include a conductive polymer, such as PEDOT, a metal nano wire, and graphene.

The first conductive layer TML1 and the second conductive layer TML2 of the multi-layer structure may include metal layers. The metal layers, for example, may have a three-layer structure of titanium/aluminum/titanium. The conductive layer of the multi-layer structure may include at least one metal layer and at least one transparent conductive layer. The second sensing insulating layer TIL2 may be disposed between the first conductive layer TML1 and the second conductive layer TML2.

The display module DM according to an embodiment may further include a reflection preventing layer that is disposed on the input sensor INS. The reflection preventing layer may further include a light shielding layer that overlaps the non-light emitting area NPXA and includes a light-absorbing material, and color filters corresponding to the light emitting areas PXA-R, PXA-G, and PXA-B. The light shielding layer is a layer having a black color, and in an embodiment, the light shielding layer may include a black coloring agent. The black coloring agent may include a black dye and a black pigment. The black coloring agent may include a metal, such as carbon black or chromium, or an oxide thereof.

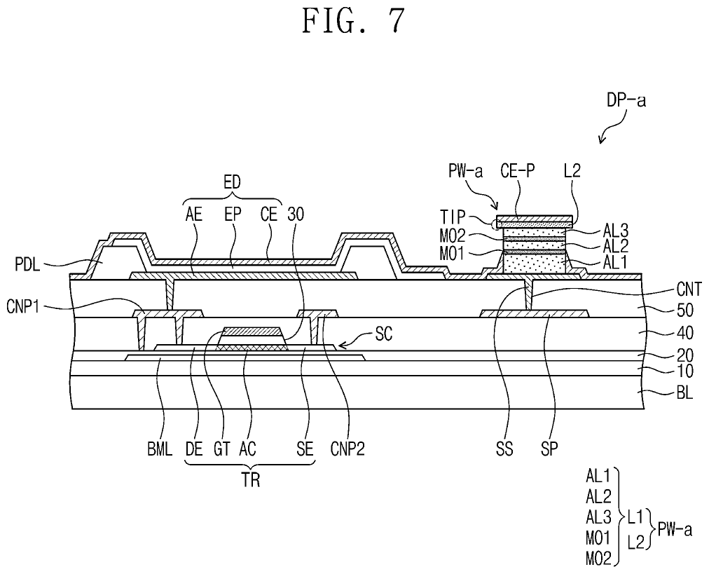

FIG. 7 is a cross-sectional view of the display panel according to an embodiment of the present disclosure.

A display panel DP-a according to an embodiment may include the base layer BL, insulating layers 10-60 that are disposed on the base layer BL, the transistor TR, a shielding electrode BML, and connecting electrodes CNP1 and CNP2, an auxiliary electrode SP, an auxiliary connecting electrode SS, the partition wall PW, the pixel definition layer PDL, and the light emitting element ED.

The base layer BL may be flexible or rigid. In an embodiment, for example, the base layer BL may include a synthetic resin film or any one of glass or metal. FIG. 7 illustrates the single-layer base layer BL, but the present disclosure is not limited thereto, and the base layer BL may be provided as a multi-layer, in which a plurality of organic layers and a plurality of inorganic layers are alternately disposed in another embodiment.

The first insulating layer 10 (i.e., a barrier layer) may be disposed on the base layer BL. The first insulating layer 10 prevents foreign substances from being introduced from the outside. The first insulating layer 10 may include at least one inorganic layer. The first insulating layer 10 prevents foreign substances from being introduced from the outside. The first insulating layer 10 may include a silicon oxide layer and a silicon nitride layer. Each of these may be provided in plural numbers, and the silicon oxide layers and silicon nitride layers may be alternately laminated.

The shielding electrode BML may be disposed on the first insulating layer 10. The shielding electrode BML may be disposed to overlap a semiconductor pattern SC of the transistor TR in a plan view. The shielding electrode BML may include a metal. In an embodiment, for example, the shielding electrode BML may include metal layers of a first layer disposed on the base layer BL and a second layer that is disposed on the first layer. The first layer may include aluminum and the second layer may include titanium.

The shielding electrode BML may block external light from reaching the transistor TR. In an embodiment of the present disclosure, the transistor TR may be a floating electrode that is isolated from other electrodes or wiring lines.

According to an embodiment, the shielding electrode BML may receive a bias voltage. The shielding electrode BML may receive a first power source voltage. The shielding electrode BML may block an electrical potential due to polarization from influencing the transistor TR. In an embodiment of the present disclosure, the shielding electrode BML may be connected to a portion of the semiconductor pattern SC through the first connecting electrode CNP1.

The second insulating layer 20 covers the shielding electrode BML and may be disposed on the first insulating layer 10. The second insulating layer 20 may prevent metal atoms or impurities from diffusing from the base layer BL to the semiconductor pattern SC on the upper side. The second insulating layer 20 may include at least one inorganic layer. The second insulating layer 20 may include a silicon oxide layer and a silicon nitride layer.

The semiconductor pattern SC may be disposed on the third insulating layer 30. The semiconductor pattern SC may include a metal oxide. The metal oxide semiconductor may include a crystalline or amorphous oxide semiconductor. In an embodiment, for example, the oxide semiconductor may include a metal oxide, such as zinc (Zn), indium (In), gallium (Ga), tin (Sn), or titanium (Ti), or a mixture of a metal, such as zinc (Zn), indium (In), and gallium (Ga)., tin (Sn), or titanium (Ti), and an oxide thereof. The oxide semiconductor may include an indium-tin oxide (ITO), an indium-gallium-zinc oxide (IGZO), a zinc oxide (ZnO), an indium-zinc oxide (IZnO), a zinc-indium oxide (“ZIO”), an indium oxide (InO), a titanium oxide (TiO), an indium-zinc-tin oxide IZTO, or a zinc-tin oxide (“ZTO”).

However, the present disclosure is not limited thereto, and the semiconductor pattern SC may include a silicon semiconductor. In an embodiment, for example, the silicon semiconductor may include amorphous silicon and polycrystalline silicon. In an embodiment, for example, the semiconductor pattern SC may include low-temperature polysilicon.

The semiconductor pattern SC may have different electrical properties depending on whether it is doped or not. The semiconductor pattern SC may include a first area of a high conductivity and a second area of a low conductivity. The first area may be doped with an N-type dopant or a P-type dopant. A P-type transistor may include a doped area that is doped with the P-type dopant, and an N-type transistor may include a doped area that is doped with the N-type dopant. The second area may be a non-doped area or an area that is doped at a concentration that is lower than a concentration of the first area.

A conductivity of the first area is greater than a conductivity of the second area, and the first area may substantially function as an electrode or a signal line. The second area may substantially correspond to the channel area (or active area) of the transistor. That is, a portion of the semiconductor pattern SC may be a channel of the transistor, another portion of the semiconductor pattern SC may be a source or a drain of the transistor, and another portion of the semiconductor pattern SC may be a connecting electrode or a connecting signal line.

The semiconductor pattern SC may include a plurality of areas SE1, AC1, and DE1 that are classified depending on whether the semiconductor pattern is reduced. An area (hereinafter, a reduction area), in which the semiconductor pattern SC is reduced, has a conductivity that is higher than a conductivity of an area (hereinafter, a non-reduction area), in which the semiconductor pattern SC is not reduced. The reduction area substantially functions as a source/drain or a signal line of the transistor. The non-reduction area substantially corresponds to a semiconductor area (or a channel) of the transistor. That is, some areas of the semiconductor pattern SC may be channel areas AC of the transistor, other areas of the semiconductor pattern SC may be source areas SE/drain areas DE of the transistor, and other portions may be used as signal transmission areas.

The third insulating layer 30 may overlap the channel area AC in a plan view. A gate GT disposed on the third insulating layer 30 may be patterned with a mask. The third insulating layer 30 may include at least one of a silicon oxide layer or a silicon nitride layer.

The gate GT may be disposed on the third insulating layer 30. The gate GT overlaps the channel area AC in a plan view. The gate GT may be a portion of a metal pattern. In a process of doping the semiconductor pattern SC, the gate GT may be a mask.

The fourth insulating layer 40 may cover the gate GT and may be disposed on the second and third insulating layers 20 and 30. The fourth insulating layer 40 may include a silicon oxide layer and a silicon nitride layer. According to an embodiment, in the fourth insulating layer 40, the silicon oxide layers and the silicon nitride layers may be alternately laminated. However, the present disclosure is not limited to this, and the fourth insulating layer 40 may include an organic material.

The first connecting electrode CNP1 and the second connecting electrode CNP2 may be disposed on the fourth insulating layer 40. A portion of the first connecting electrode CNP1 may be connected to the shielding electrode BML through a contact hole that passes through the second and fourth insulating layers 20 and 40, and the other portions of the first connecting electrode CNP1 may be connected to the drain area DE through a contact hole that penetrates through the fourth insulating layer 40. A portion of the second connecting electrode CNP2 may be connected to the source area SE through a contact hole that passes through the fourth insulating layer 40.

The display panel DP-a according to the embodiment may further include an auxiliary electrode SP that is disposed on the fourth insulating layer 40. The auxiliary electrode SP is patterned through the same process as patterning processes of the first connecting electrode CNP1 and the second connecting electrode CNP2, and thus may include the same material as materials of the first connecting electrode CNP1 and the second connecting electrode CNP2.

The auxiliary electrode SP, the first connecting electrode CNP1, and the second connecting electrode CNP2 may include a metal layer including first to third layers that are sequentially laminated on the fourth insulating layer 40. The first and third layers may include titanium, and the second layer may include aluminum.

The fifth insulating layer 50 (an inter-layer insulation layer) may cover the auxiliary electrode SP, the first connecting electrode CNP1, and the second connecting electrode CNP2, and may be disposed on the fourth insulating layer 40. The fifth insulating layer 50 may include polyimide.

The light emitting element ED may include an anode AE (or a first electrode), a light emitting layer EL, and a cathode CE (or second electrode). The anode AE of the light emitting element ED may be disposed on the fifth insulating layer 50. The anode AE can be a (semi-) transmissive electrode or a reflective electrode. The anode AE may include a laminated structure of sequentially laminated ITO/Ag/ITO. The location of the anode AE and the cathode CE may be replaced by each other.

The pixel definition layer PDL may be disposed on the fifth insulating layer 50. The pixel definition layer PDL may be an organic layer containing polyimide. The pixel definition layer PDL may have a property of absorbing light, and for example, the pixel definition layer PDL may have a black color. The pixel definition layer PDL may include a black coloring agent. The black coloring agent may include a black dye and black pigment. The black coloring agent may include a metal, such as carbon black or chromium, or an oxide thereof. The pixel definition layer PDL may correspond to a light shielding pattern having light shielding characteristics. An opening that exposes a portion of the anode AE may be defined in the pixel definition layer PDL.

The auxiliary connecting electrode SS may be disposed on the fifth insulating layer 50. As the auxiliary connecting electrode SS is patterned through the same process as a patterning process of the anode AE, the auxiliary connecting electrode SS may include the same material as a material of the anode AE. The auxiliary connecting electrode SS may be connected to the auxiliary electrode SP through a contact hole CNT that is defined by the fifth insulating layer 50.

The display panel DP-a according to the embodiment may include a partition wall PW-a. The partition wall PW-a according to an embodiment may include a lower layer L1 and an upper layer L2 that is disposed on the lower layer L1. The lower layer L1 may be directly disposed on the auxiliary connecting electrode SS.

The lower layer L1 may include a conductive material. The lower layer L1 according to the present disclosure may be provided as a multi-layer, in which different metal layers are laminated. In an embodiment, for example, the lower layer L1 may include first to fifth layers AL1, MO1, AL2, MO2, and AL3 that are sequentially laminated on the pixel definition layer PDL. According to the present disclosure, contact resistances of the second layer MO1 and the fourth layer MO2 to the upper layer L2 may be lower than contact resistances of the first layer AL1, the third layer AL2, and the fifth layer AL3 to the upper layer L2.

The first layer AL1, the third layer AL2, and the fifth layer AL3 may include the same first material, and the second layer MO1 and the fourth layer MO2 may include the same second material that is different from the first material. In an embodiment, for example, the first layer AL1, the third layer AL2, and the fifth layer

AL3 may each include aluminum (Al), and the second layer MO1 and the fourth layer MO2 may each include any one of molybdenum (Mo) and molybdenum-alloy. A description of the lower layer L1 may correspond to the partition wall PW described in FIGS. 5 and 6.

The upper layer L2 may include a metal or a non-metal. In an embodiment, for example, the metal may include gold (Au), silver (Ag), aluminum (Al), magnesium (Mg), lithium (Li), molybdenum (Mo), titanium (Ti), copper (Cu), or an alloy. The non-metal may include silicon, a silicon oxide, a silicon nitride, a silicon oxynitride, a metal oxide, or a metal nitride, or a combination thereof, and the metal oxide may include a transparent conductive oxide (TCO).

According to the embodiment, the cathode CE may contact a side surface of the partition wall PW-a. Accordingly, the cathode CE may be connected to the auxiliary electrode SP through the partition wall PW-a including a conductive material and the auxiliary connecting electrode SS.

An electrode pattern CE-P may be disposed on the upper layer L2. The electrode pattern CE-P may be a portion that is disconnected from the cathode CE by the tip part TIP of the partition wall PW-a. Accordingly, the electrode pattern CE-P may be disposed on the upper layer L2 and may include the same material as a material of the cathode CE. The portions of the cathode CE, which are disconnected by the tip part TIP of the partition wall PW-a may be electrically connected to each other while contacting the side surface of the partition wall PW-a.

A light control layer including quantum dots may be disposed on the display panel DP-a according to the embodiment. The light control layer may change properties of a source light provided by the display panel DP-a.

According to the embodiment, to prevent a voltage drop (IR Drop) phenomenon of the cathode CE, it may be connected to the auxiliary electrode SP of a low resistance through the partition wall PW-a. The auxiliary electrode SP may be provided with the second driving voltage ELVSS described in FIG. 3B. As the second driving voltage ELVSS is provided within 0.2 V, the voltage drop (IR Drop) phenomenon of the cathode CE may be prevented. Accordingly, the display panel DP-a of an improved luminance uniformity may be provided.

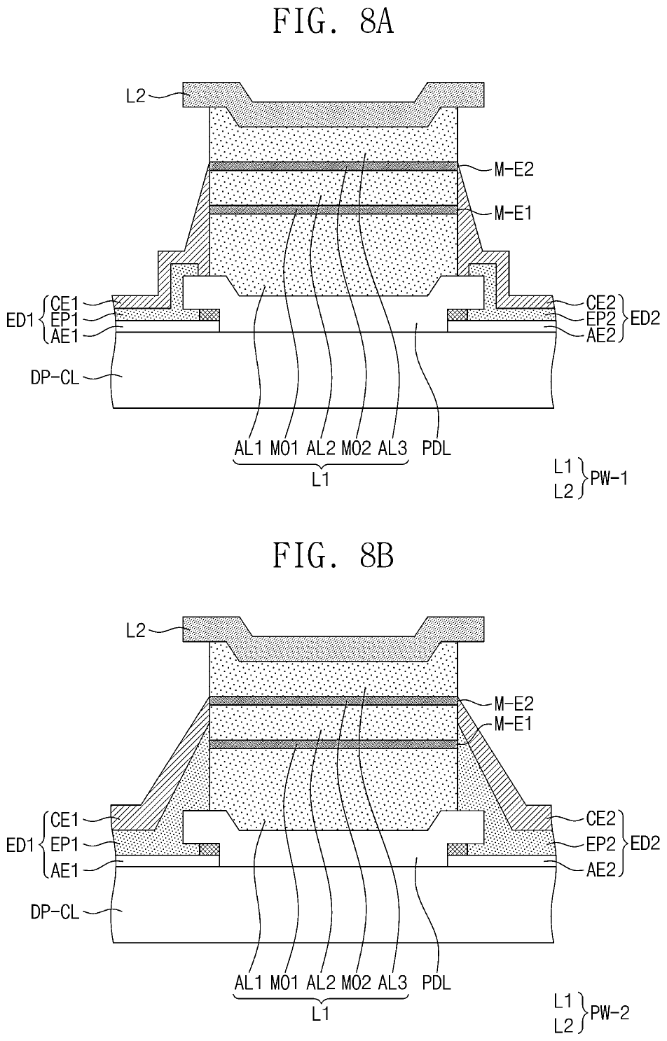

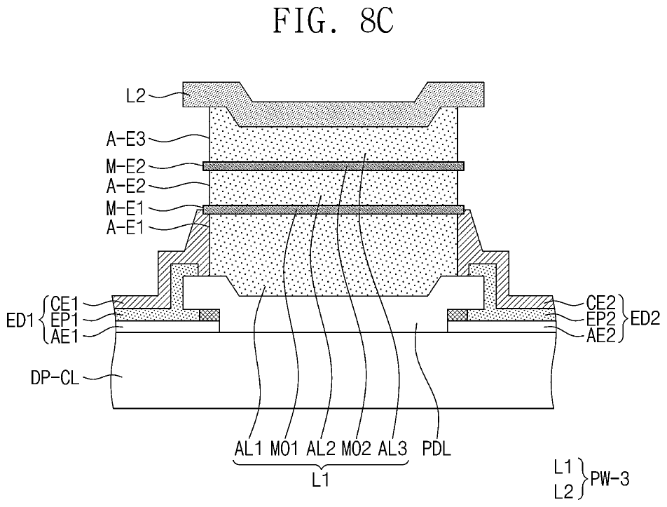

FIG. 8A is a cross-sectional view illustrating a portion of the partition wall according to another embodiment of the present disclosure. FIG. 8B is a cross-sectional view illustrating a portion of the partition wall according to still another embodiment of the present disclosure. FIG. 8B is a cross-sectional view illustrating a portion of the partition wall according to yet another embodiment of the present disclosure. The same/similar reference numerals are used for components that are the same/similar to those described in FIGS. 5 and 6, and a repeated description will be omitted. Embodiments regarding a partition wall that will be described in FIGS. 8A to 8C may be applied to the partition wall described in FIGS. 5 and 6.

Referring to FIG. 8A, it may include a partition wall PW-1 that is disposed on the circuit element layer DP-CL. The partition wall PW-1 according to an embodiment may include the lower layer L1 and the upper layer L2 that is disposed on the lower layer L1.

The lower layer L1 may include a conductive material. The lower layer L1 according to the present disclosure may be provided as a multi-layer, in which different metal layers are laminated. In an embodiment, for example, the lower layer L1 may include the first to fifth layers AL1, MO1, AL2, MO2, and AL3 that are sequentially laminated on the circuit element layer DP-CL. According to the present disclosure, contact resistances of the second layer MO1 and the fourth layer MO2 to the upper layer L2 may be lower than contact resistances of the first layer AL1, the third layer AL2, and the fifth layer AL3 to the upper layer L2.

According to the embodiment, the first layer AL1, the third layer AL2, and the fifth layer AL3 may each include aluminum (Al), and the second layer MO1 and the fourth layer MO2 may each include any one of molybdenum (Mo) and a molybdenum-alloy. A description of the lower layer L1 may correspond to the partition wall PW described in FIGS. 5 and 6. The upper layer L2 may include titanium (Ti).

According to this embodiment, the cathodes CE1 and CE2 included in each of the light emitting elements ED1 and ED2 may contact the first to fourth side surfaces AL1, MO1, AL2, and MO2. In particular, the cathodes CE1 and CE2 may contact a side surface M-E1 of the second layer MO1 and a side surface M-E2 of the fourth layer MO2, which have a relatively low contact resistance. The cathodes CE1 and CE2 may expose a side surface of the fifth layer AL3.

Referring to FIG. 8B, it may include a partition wall PW-2 that is disposed on the circuit element layer DP-CL. The partition wall PW-2 according to an embodiment may include the lower layer L1 and the upper layer L2 that is disposed on the lower layer L1.

The lower layer L1 may include a conductive material. The lower layer L1 according to the present disclosure may be provided as a multi-layer, in which different metal layers are laminated. In an embodiment, for example, the lower layer L1 may include the first to fifth layers AL1, MO1, AL2, MO2, and AL3 that are sequentially laminated on the circuit element layer DP-CL. According to the present disclosure, contact resistance of the second layer MO1 and the fourth layer MO2 to the upper layer L2 may be lower than contact resistances of the first layer AL1, the third layer AL2, and the fifth layer AL3 to the upper layer L2.

According to the embodiment, the first layer AL1, the third layer AL2, and the fifth layer AL3 may each include aluminum (Al), and the second layer MO1 and the fourth layer MO2 may each include any one of molybdenum (Mo) and molybdenum-alloy. A description of the lower layer L1 may correspond to the partition wall PW described in FIGS. 5 and 6. The upper layer L2 may include titanium (Ti).

According to the embodiment, the light emission patterns EP1 and EP2 included in each of the light emitting elements ED1 and ED2 may contact a portion of a side surface of the first layer AL1, a side surface M-E1 of the second layer MO1, and a side surface of the third layer AL2. The cathodes CE1 and CE2 may contact the remaining portions of the side surfaces of the third layer AL2 and a side surface M-E2 of the fourth layer MO2. Accordingly, the cathodes CE1 and CE2 do not contact the side surface M-E1 of the second layer MO1, and may contact only the side surface M-E2 of the fourth layer MO2.

Referring to FIG. 8C, it may include a partition wall PW-3 that is disposed on the circuit element layer DP-CL. The partition wall PW-3 according to an embodiment may include the lower layer L1 and the upper layer L2 disposed on the lower layer L1.

The lower layer L1 may include a conductive material. The lower layer L1 according to the present disclosure may be provided as a multi-layer, in which different metal layers are laminated. In an embodiment, for example, the lower layer L1 may include the first to fifth layers AL1, MO1, AL2, MO2, and AL3 that are sequentially laminated on the circuit element layer DP-CL. According to the present disclosure, contact resistances of the second layer MO1 and the fourth layer MO2 to the upper layer L2 may be lower than contact resistances of the first layer AL1, the third layer AL2, and the fifth layer AL3 to the upper layer L2.

According to the embodiment, the first layer AL1, the third layer AL2, and the fifth layer AL3 may each include aluminum (Al), and the second layer MO1 and the fourth layer MO2 may each include any one of molybdenum (Mo) and molybdenum-alloy. A description of the lower layer L1 may correspond to the partition wall PW described in FIGS. 5 and 6. The upper layer L2 may include titanium (Ti).

According to an embodiment, a side surface M-E1 of the second layer MO1 and a side surface M-E2 of the fourth layer MO2 may protrude in a direction that faces the light emission patterns EP1 and EP2 as compared with a side surface A-E1 of the first layer AL1, a side surface A-E2 of the third layer AL2, and a side surface A-E3 of the fifth layer AL3. This may be formed into an undercut shape due to a difference in etching rate. Because the partition wall PW-2 according to the embodiment has an undercut shape for each adjacent layer, the light emission patterns EP1 and EP2 and the cathodes CE1 and CE2 may be individually patterned more easily.

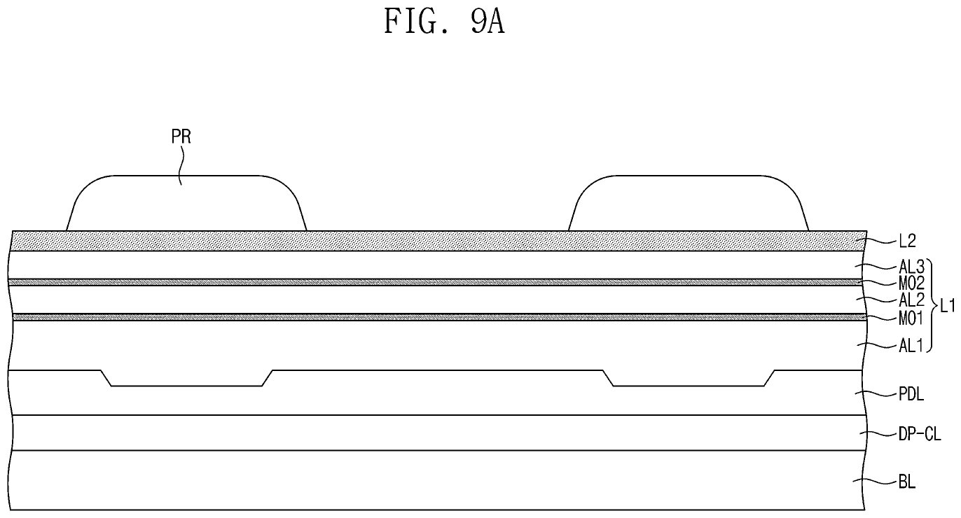

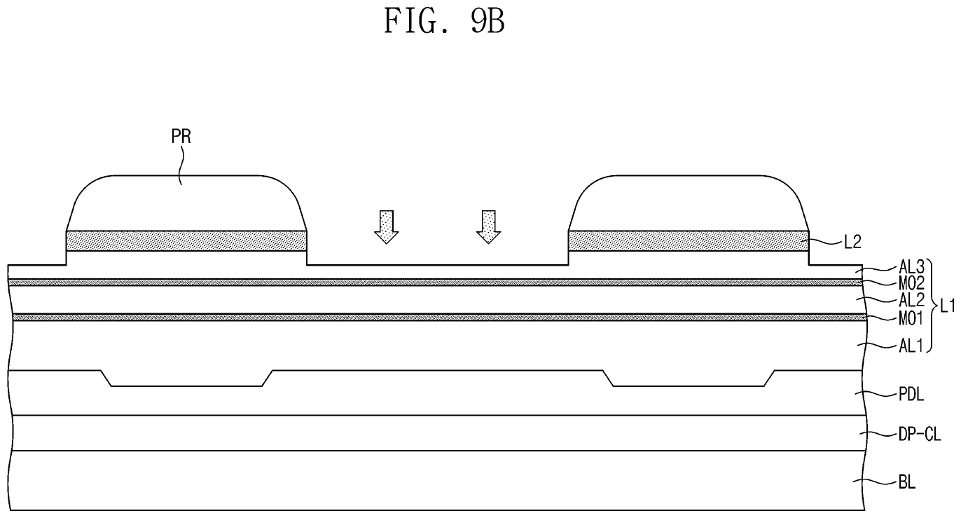

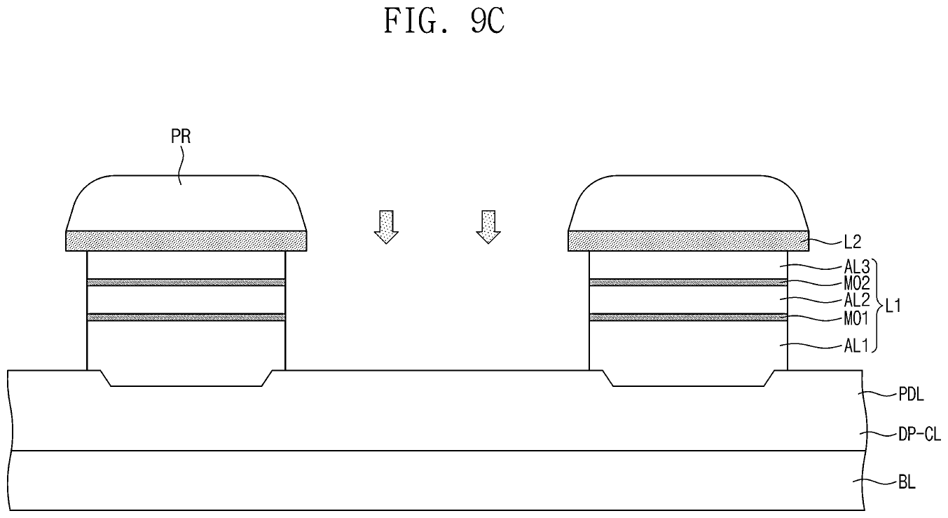

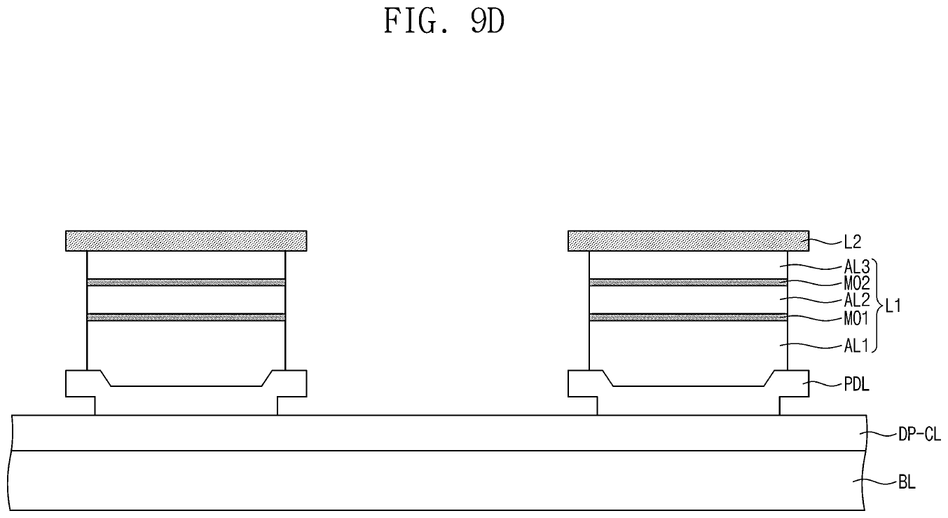

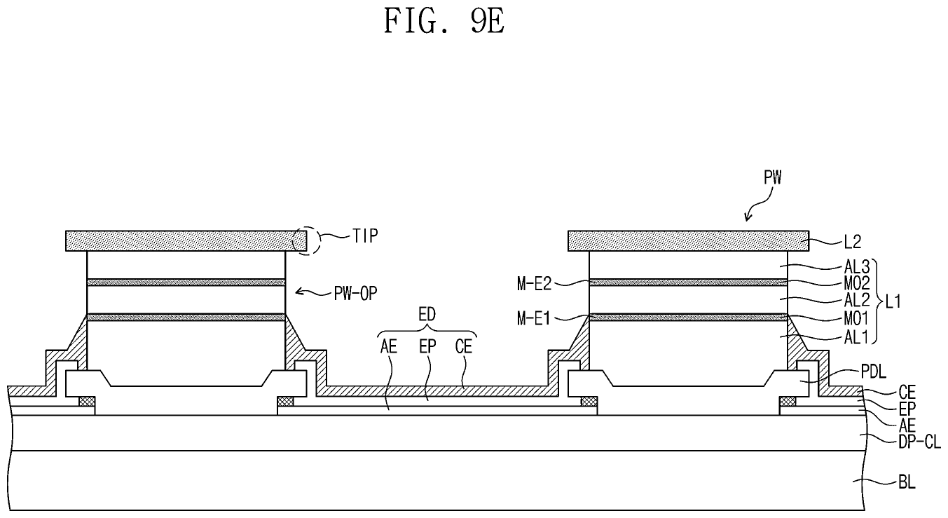

FIGS. 9A to 9E are cross-sectional views illustrating a method for manufacturing a display panel according to an embodiment of the present disclosure. The same/similar reference numerals are used for components that are the same/similar to those described in FIGS. 5 and 6, and a repeated description will be omitted.

Referring to FIG. 9A, the method for manufacturing a display panel according to an embodiment may include an operation of forming the circuit element layer DP-CL on the base layer BL, an operation of forming the pixel definition layer PDL on the circuit element layer DP-CL, an operation of forming the lower layer L1 on the pixel definition layer PDL, an operation of forming the upper layer L2 on the lower layer L1, and an operation of forming a photoresist layer PR on the upper layer L2.

The circuit element layer DP-CL may be formed through a common process of manufacturing a circuit element by forming an insulating layer, a semiconductor layer, a conductive layer through a scheme, such as coating or deposition, selectively patterning the insulating layer, the semiconductor layer, and the conductive layer through photography and etching processes, and forming a semiconductor pattern, a conductive pattern, and signal lines. The pixel definition layer PDL may include polyimide.

The lower layer L1 may be formed as a multiple layer, in which different metal layers laminated. In an embodiment, for example, in the lower layer L1, the first to fifth layers AL1, MO1, AL2, MO2, and AL3 may be sequentially formed on the pixel definition layer PDL. According to the present disclosure, contact resistances of the second layer MO1 and the fourth layer MO2 to the upper layer L2 may be lower than contact resistances of the first layer AL1, the third layer AL2, and the fifth layer AL3 to the upper layer L2.

In the lower layer L1, thicknesses of the first layer AL1, the third layer AL2, and the fifth layer AL3 may each be formed to be not less than 1000 Å and not more than 3000 Å. In the lower layer L1, thicknesses of the second layer MO1 and the fourth layer MO2 may each be formed to be not less than 500 Å and not more than 1500 Å.

According to an embodiment, the thicknesses of the first layer AL1, the third layer AL2, and the fifth layer AL3 may be different from each other. In an embodiment, for example, the thickness of the first layer AL1 may be 2500 Å, the thickness of the third layer AL2 may be 1500 Å, and the thickness of the fifth layer AL3 may be 1500 Å. Then, the thickness of the second layer MO1 and the fourth layer MO2 may each be 800 Å, and the thickness of the upper layer L2 may be 2000 Å. The upper layer L2 may be formed on the fifth layer AL3. The upper layer L2 may include titanium (Ti). The method for forming the layers included in the lower layer L1 and the upper layer L2 is not limited to any one method as long as it is a process for forming a metal layer.

The photoresist layer PR may be formed on the upper layer L2. The photoresist layer PR is not limited to any one as long as it is used in the photoresist process.

Thereafter, referring to FIG. 9B, the method for manufacturing a display panel according to an embodiment may include a first etching operation. In the first etching operation, at least a portion of the upper layer L2 and the fifth layer AL3 may be removed through a dry etching process while using the photoresist layer PR as a mask.

Thereafter, referring to FIG. 9C, the method for manufacturing a display panel according to an embodiment may include a second etching operation. In the second etching operation, at least a portion of the first to fourth layers AL1, MO1, AL2, and MO2 and the fifth layer AL3 may be removed through a wet etching process. The etchant used in the wet etching process may be a phosphorus and nitrogen-based FAN-based etchant.

Thereafter, referring to FIG. 9D, the method for manufacturing a display panel according to an embodiment may further include an operation of etching the pixel definition layer PDL.

Thereafter, referring to FIG. 9E, the method for manufacturing a display panel according to an embodiment may further include an operation of forming the light emitting element ED. The anode AE, the light emission pattern EP, and the cathode CE included in the light emitting element ED may be individually patterned to be displaced in the partition wall opening PW-OP defined by the partition wall PW.

According to the embodiment, due to the difference between etching rates of the lower layer L1 and the upper layer L2, the components included in the light emitting element ED may be separated through the undercut-shaped tip portion TIP and may be easily patterned in the partition wall opening PW-OP. Furthermore, because the lower layer L1 includes layers including a molybdenum alloy having a low contact resistance to the upper layer L2, the display panel having an enhanced coupling force between the lower layer L1 and the upper layer L2 may be provided.

According to the present disclosure, because a light emitting layer may be patterned with no mask, a process reliability may be improved and a high resolution may be easily implemented. Furthermore, because the molybdenum alloy layer is included in the lower layer of the partition wall, a contact resistance between the lower layer and the upper layer may be decreased.

Although the present disclosure has been described with reference to the embodiments, it will be appreciated by an ordinary skilled in the art, to which the present disclosure pertains, that the present disclosure may be modified and changed within the scope of the appended claims without departing from the spirits and technical field of the present disclosure.

Therefore, the technical scope of the present disclosure should not be limited to the detailed description of the specification, but should be determined by the claims.

What is claimed is:

1. A display panel comprising:
a base layer including a light emitting area and a non-light emitting area being adjacent to the light emitting area;
a light emitting element including a first electrode disposed in the light emitting area, a second electrode disposed on the first electrode, and a light emission pattern disposed between the first electrode and the second electrode; and
a partition wall including a lower layer disposed in the non-light emitting area and an upper layer disposed on the lower layer,
wherein the second electrode contacts a side surface of the lower layer, and
wherein the lower layer includes layers containing different metals.

2. The display panel of claim 1, wherein the lower layer includes:
a first layer, a second layer, a third layer, a fourth layer, and a fifth layer, which are laminated sequentially,
wherein contact resistances of the second layer and the fourth layer to the upper layer are lower than contact resistances of the first layer, the third layer, and the fifth layer to the upper layer.

3. The display panel of claim 2, wherein the first layer, the third layer, and the fifth layer each include aluminum, and
Wherein the second layer and the fourth layer each include any one of molybdenum and a molybdenum alloy.

4. The display panel of claim 3, wherein the molybdenum alloy includes molybdenum, nickel, and titanium.

5. The display panel of claim 4, wherein a content of nickel and titanium is not more than 50% of a total weight of the molybdenum alloy.

6. The display panel of claim 3, wherein a thickness of the lower layer is 5000 angstroms (Å) to 10000 Å, and
wherein a thickness of the upper layer is 1000 Å to 2000 Å.

7. The display panel of claim 3, wherein thicknesses of the first layer, the third layer, and the fifth layer are each 1000 Å to 3000 Å, and
wherein thicknesses of the second layer and the fourth layer are each 500 Å to 1500 Å.

8. The display panel of claim 3, wherein the upper layer includes titanium.

9. The display panel of claim 2, wherein side surfaces of the first to fifth layers are aligned with each other.

10. The display panel of claim 2, wherein side surfaces of the second layer and the fourth layer each protrude further in a direction facing the light emitting area than the first layer, the third layer, and the fifth layer.

11. The display panel of claim 2, wherein the second electrode contacts the second layer and exposes the fourth layer.

12. The display panel of claim 2, wherein the second electrode is spaced apart from the second layer and contacts the fourth layer.

13. The display panel of claim 2, wherein the second electrode contacts the second layer and the fourth layer.

14. The display panel of claim 1, wherein a side surface of the upper layer protrudes in a direction facing the light emitting area further than the side surface of the lower layer.

15. The display panel of claim 1, further comprising:
a pixel definition layer disposed on the base layer, and by which an opening exposing at least a portion of the first electrode is defined,
wherein the pixel definition layer includes an inorganic material, and
wherein the lower layer is disposed on the pixel definition layer.

16. The display panel of claim 15, wherein a partition wall opening overlapping the opening is defined by the partition wall.

17. The display panel of claim 16, further comprising:
an encapsulation layer including a lower inorganic layer covering the light emitting element and the partition wall, an upper inorganic layer disposed on the lower inorganic layer, and an organic layer disposed between the lower inorganic layer and the upper inorganic layer and disposed in the partition wall opening.

18. The display panel of claim 17, further comprising:
a dummy pattern disposed on the upper layer, and including a same material as at least one of the light emission pattern or the second electrode,
wherein the dummy pattern is covered by the lower inorganic layer.

19. The display panel of claim 18, wherein a dummy recess exposing an upper surface of the upper layer is defined by the dummy pattern, and
wherein the organic layer contacts the upper surface of the upper layer.

20. The display panel of claim 1, further comprising:
a transistor disposed on the base layer;
a connecting electrode connecting the transistor and the first electrode;
an auxiliary electrode disposed in a same layer as a layer of the connecting electrode;
an inter-layer insulation layer covering the connecting electrode and the auxiliary electrode, and on which the first electrode is disposed;
a pixel definition layer, by which an opening exposing at least a portion of the first electrode is defined; and
an auxiliary connecting electrode disposed on the inter-layer insulation layer, and connected to the auxiliary electrode through a contact hole defined in the inter-layer insulation layer,
wherein the lower layer is disposed on the auxiliary connecting electrode.
